(19) United States
(12) Patent Application Publication
(10) Pub. No.: US 2015/0227419 A1
(43) Pub. Date: Aug. 13, 2015

(54) ERROR CORRECTION DECODER BASED ON LOG-LIKELIHOOD RATIO DATA

(71) Applicant: Kabushiki Kaisha Toshiba, Minato-ku (JP)

(72) Inventors: Kenji Sakaue, Yokohama-shi (JP); Kouji Saitou, Tokyo (JP); Tatsuyuki Ishikawa, Yokohama-shi (JP); Kazuhiro Ichikawa, Yamato-shi (JP); Naoaki Kokubun, Yokohama-shi (JP); Hironori Uchikawa, Yokohama-shi (JP)

(73) Assignee: Kabushiki Kaisha Toshiba, Minato-ku (JP)

(21) Appl. No.: 14/308,985

(22) Filed: Jun. 19, 2014

Related U.S. Application Data
(60) Provisional application No. 61/939,059, filed on Feb. 12, 2014.

(51) Int. Cl. G06F 11/10; H03M 13/11; G11C 29/52

(52) U.S. Cl. CPC G06F 11/1068; G11C 29/52; H03M 13/1102

(57) ABSTRACT

According to one embodiment, an error correction decoder includes a selecting section, calculating section, check section, and updating section. The selecting section selects data used for matrix processing applied to a process target row from LLR data stored in the first memory section based on a check matrix, and stores the data in a second memory section. The calculating section executes the matrix processing based on the data stored in the second memory section, and writes updated data back to the second memory section. The check section checks a parity based on a calculating result of the calculating section. The updating section updates the LLR data of the first memory section based on the updated data of the second memory section.

### CROSS-REFERENCE TO RELATED APPLICATIONS

This application claims the benefit of U.S. Provisional Application No. 61/939,059, filed Feb. 12, 2014, the entire contents of which are incorporated herein by reference.

### FIELD

Embodiments described herein relate generally to an error correction decoder based on Log-Likelihood Radio (LLR) data.

### BACKGROUND

For example, an error correction code is used for correcting data read from a nonvolatile semiconductor memory such a NAND type flash memory. A low density parity check (LDPC) code which is a type of the error correction code has a high error correction capability. A decoding capability is improved in proportion to an increase in code length of the LDPC code. The code length used for the NAND type flash memory is on the order of, e.g. 10 Kbits.

### BRIEF DESCRIPTION OF THE DRAWINGS

FIG. 1 is a block diagram illustrating an example of a schematic structure of an error correction decoder according to a first embodiment.

FIG. 2 is a drawing illustrating an example of a relationship of a check matrix, LMEM and LREG according to the first embodiment.

FIG. 3 is a timing chart illustrating an example of a process of the error correction decoder according to the first embodiment.

FIG. 4 is a block diagram illustrating an example of a schematic structure of an error correction decoder according to a second embodiment.

FIG. 5 is a view illustrating an example of a check matrix according to the second embodiment.

FIG. 6 is a timing chart illustrating an example of a process of the error correction decoder according to the second embodiment.

FIG. 7 is a drawing illustrating an example of a check matrix according to a third embodiment.

FIG. 8 is a timing chart illustrating an example of a process of the error correction decoder according to the third embodiment.

FIG. 9 is a timing chart illustrating an example of a process of an error correction decoder according to a fourth embodiment.

FIG. 10 is a view illustrating an example of a check matrix of LDPC.

FIG. 11 is a view illustrating an example of the check matrix represented as a Tanner graph.

FIG. 12A is a view illustrating an example of a check matrix composed by combining a plurality of matrix blocks.

FIG. 12B is a view illustrating an example of shift values of diagonal components of the matrix blocks.

FIG. 13A is a view illustrating an example of a matrix block of a shift value 0.

FIG. 13B is a view illustrating an example of a matrix block of a shift value 1.

FIG. 14A is view illustrating a first example of a process based on TMEM variables.

FIG. 14B is view illustrating a second example of a process based on TMEM variables.

FIG. 14C is view illustrating a third example of a process based on TMEM variables.

FIG. 15 is a view illustrating an example of a configuration of an LDPC decoder.

FIG. 16 is a flowchart illustrating an example of an operation of the LDPC decoder shown in FIG. 15.

FIG. 17 is a view illustrating an example of a procedure for updating LLRs corresponding to variable nodes.

FIG. 18 is a flowchart illustrating an example of an operation of a first mode of a check-node based parallel process.

FIG. 19 is a view illustrating an example of a concept of the LMEM according to the first mode.

FIG. 20 is a block diagram illustrating an example of a schematic structure of an LDPC decoder according to the first mode.

FIG. 21 is a block diagram illustrating an example of a concrete structure of the LDPC decoder according to the first mode.

FIG. 22 is a view illustrating an example of an operation of the LDPC decoder according to the first mode.

FIG. 23 is a block diagram illustrating an example of a schematic structure of an LDPC decoder according to a second mode of the check-node based parallel process.

FIG. 24 is a view illustrating an example of an operation of the LDPC decoder according to the second mode.

FIG. 25 is a view illustrating an example of a check matrix according to a third mode of the check-node based parallel process.

FIG. 26 is a view illustrating a first example of a control between row processes using the check matrix according to the third mode.

FIG. 27 is a view illustrating a second example of a control between row processes using the check matrix according to the third mode.

FIG. 28 is a view illustrating other example of a check matrix according to the third mode.

FIG. 29 is a view illustrating an example of a control between row processes using other example of the check matrix according to the third mode.

FIG. 30 is a block diagram illustrating an example of a concrete structure of the LDPC decoder according to a fourth mode of the check-node based parallel process.

FIG. 31 is a view illustrating an example of a check matrix according to the fourth mode.

FIG. 32 is a flowchart illustrating an example of an operation of the LDPC decoder according to a fourth mode.

FIG. 33 is a flowchart illustrating a modified example of an operation of the LDPC decoder according to the fourth mode.

### DETAILED DESCRIPTION

Embodiments will be described hereinafter with reference to drawing. In a following description, the same reference numerals denote nearly the same functions and structure elements, and a repetitive description thereof will be given if necessary.

In the Embodiments, an error correction decoder includes a converting section, selecting section, calculating section, and updating section. The converting section converts error correction code (ECC) data into LLR data and stores the LLR data in a first memory section. The selecting section selects, based on a check matrix including matrix blocks (unit blocks) arranged along rows and columns, data (partial LLR data or LLR) used for matrix processing applied to a process target row among the rows from the LLR data stored in the first memory section, and stores the data in a second memory section. The calculating section executes the matrix processing based on the data stored in the second memory section, and writes updated data back to the second memory section. The parity check section checks a parity based on a calculating result of the calculating section. The updating section updates the LLR data stored in the first memory section based on the updated data stored in the second memory section.

### First Embodiment

This embodiment explains an error correction decoder, which corrects an error of data read out from a nonvolatile semiconductor memory. However, error corrected data is not limited to data read out from the nonvolatile semiconductor memory. The error corrected data may be data read out from other memory or data received by a communication device.

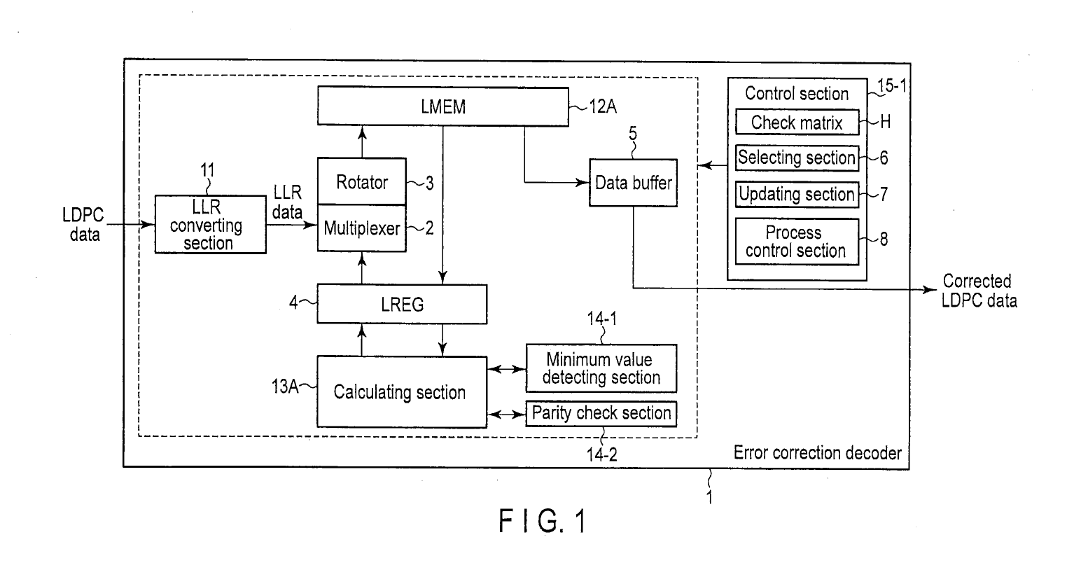

FIG. 1 is a block diagram illustrating an example of a schematic structure of an error correction decoder according to this embodiment.

In this embodiment, an error correction decoder 1 converts ECC data read out from a nonvolatile semiconductor memory into LLR data (likelihood information) based on a set LLR conversion table, and produces corrected ECC data by decoding based on the LLR data.

In this embodiment, it is explained that LDPC decoding is applied to an example of ECC decoding, and LDPC data is applied to an example of the ECC data (frame data). However, error correction decoding and the error corrected data are not limited to them.

A NAND type flash memory may be an example of the nonvolatile semiconductor memory. However, some other nonvolatile semiconductor memory may be used, such as a NOR type flash memory, MRAM (Magnetoresistive Random Access Memory), PRAM (Phase-change Random Access Memory), ReRAM (Resistive Random Access Memory), or FeRAM (Ferroelectric Random Access Memory), for instance.

The error correction decoder 1 is an LDPC decoder of a parallel process mode which parallel processes a plurality of variable nodes (vns) based on a check node (cn) (a check-node based parallel process mode). It should be noted that the variable nodes may be called as bit nodes. The check node, the variable node, and a normal check-node based parallel process mode will be explained in detail at a section “Explanation of check-node based parallel process mode” in a fifth embodiment.

The error correction decoder 1 includes a control section 15-1, an LLR converting section 11, a multiplexer 2, a rotator 3, an LMEM 12A, an LREG 4, a calculating section 13A, a minimum value detecting section 14-1, a parity check section 14-2, and a data buffer 5.

The control section 15-1 includes a check matrix H, a selecting section 6, an updating section 7, and a process control section 8. The control section 15-1 controls an operation of each structure element of the error correction decoder 1 such as the LLR converting section 11, the multiplexer 2, the rotator 3, the LMEM 12A, the LREG 4, the calculating section 13A, the minimum value detecting section 14-1, the parity check section 14-2, and the data buffer 5.

In this embodiment, the LMEM 12A and the LREG 4 constitute a hierarchical memory structure concerning the LLR data.

A Static Random Access Memory (SRAM) may be used as the LMEM 12A, for instance, but other memory such as a Dynamic Random Access Memory (DRAM) may be used as the LMEM 12A.

A register may be used as the LREG 4, for instance, but it is possible to use other memory as the LREG 4. The LREG 4 is between the LMEM 12A and the calculating section 13A, achieves much quicker access than the LMEM 12A, and functions as a cache of the LMEM 12A.

The LLR converting section 11 receives the LDPC data read out from the nonvolatile semiconductor memory, converts the LDPC data into the LLR data based on the set LLR conversion table, and stores the LLR data in the LMEM 12A via the multiplexer 2 and the rotator 3. The LLR data is an example of reliability information.

The LLR conversion table indicating a corresponding relationship between the LDPC data and the LLR data is generated in advance by a statistical method.

The multiplexer 2 receives the LLR data from the LLR converting section 11, and sends the LLR data to the rotator 3. Furthermore, the multiplexer 2 receives updated LLRs from the LREG 4, and sends the updated LLRs to the rotator 3. The multiplexer 2 may be a selector.

The rotator 3 receives the LLR data from the LLR converting section 11 via the multiplexer 2, and stores the LLR data at a suitable location of the LMEM 12A. The rotator 3 receives the updated LLRs from the LREG 4 via the multiplexer 2, and stores the updated LLRs at a suitable location of the LMEM 12A.

The LMEM 12A is a variable node memory section, and stores the LLR data. The LLR data stored in the LMEM 12A is updated when the matrix processing is executed.

The check matrix H has a structure in which the matrix blocks are arranged along rows and columns.

The selecting section 6 selects LLRs from the LLR data in the LMEM 12A based on the check matrix H. The selected LLRs are portions of the LLR data, and are used for matrix processing, which is applied to a row of the matrix blocks in the check matrix H. The selecting section 6 stores selected LLRs in the LREG 4. The LLRs simultaneously read out from the LMEM 12A by the selecting section 6 and stored in the LREG 4, are LLRs that correspond to all the variable nodes that have connective relation to a process target check node.

The LREG 4 stores the LLRs that are read out from the LMEM 12A and are required for the matrix processing which will be applied to a process target row in the calculating section 13A.

The parity check section 14-2 checks a parity based on the calculating result obtained by the calculating section 13A.

The minimum value detecting unit 14-1 detects a minimum value α of absolute values of values βs obtained by the matrix processing applied to a preceding row in the check matrix H.

The calculating section 13A executes the matrix processing for each row in the check matrix H based on the LLRs stored in the LREG 4, and writes the updated LLRs being the calculating result, back in the LREG 4. More specifically, the calculating section 13A subtracts the minimum value α for a preprocess from each of the LLRs of all the variable nodes that have connective relation to the process target check node to obtain values βs, and temporarily stores the values βs in a β memory section 9 such as a register. Furthermore, the calculating section 13A calculates a sum of each individual value β and the minimum value α, and produces each individual updated LLR (=β+α).

The updating section 7 updates the LLR data by storing the updated LLRs stored in the LREG 4 at suitable locations of the LMEM 12A via the multiplexer 2 and the rotator 3.

The process control section 8 controls a pipeline process of the selecting section 6, the calculating section 13A, and the updating section 7.

The data buffer 5 temporarily stores corrected LDPC data, which is updated LLR data and is stored in the LMEM 12A.

The control section 15-1 output the corrected LDPC data stored the data buffer 5.

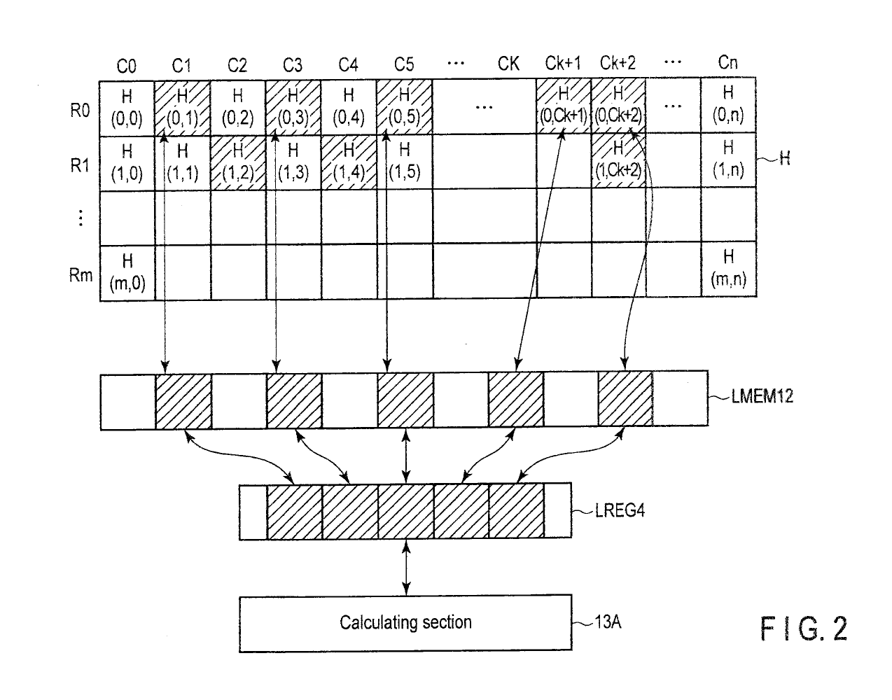

FIG. 2 is a drawing illustrating an example of a relationship of the check matrix H, the LMEM 12A and the LREG 4 according to this embodiment.

In the FIG. 2, the check matrix H includes M+1 rows R0-Rm and N+1 columns C0-Cn, and the check matrix H includes (M+1)×(N+1) matrix blocks H(0,0)-H(m,n). It may be considered that the matrix blocks H(0,k+1)-H(0,n), H(1,k+1)-H(1,n), . . . , H(m,k+1)-H(m,n) indicated by columns Ck+1-Cn are parity block portions.

At first, for a first row R0, the selecting section 6 selects LLRs required for the matrix processing for the row R0 from the LMEM 12A, and write the selected LLRs to the LREG 4. For instance, the LLRs required for the matrix processing for the row R0 are data pieces that correspond to valid blocks H(0,1), H(0,3), H(0,5), H(0,Ck+1), and H(0,Ck+2), which are non-zero blocks in the row R0.

Then, the calculating section 13A reads out the LLRs which are required for the matrix processing for the row R0 and are stored in the LREG 4, executes the matrix processing, and writes the updated LLRs back to the LREG 4.

Then, the updating section 7 writes the updated LLRs of the LREG 4 back in the suitable locations in the LMEM 12A using the multiplexer 2 and the rotator 3.

Then, for a row R1, the selecting section 6 selects the LLRs required for the matrix processing for the row R1 from the LMEM 12A, and write the selected LLRs to the LREG 4. For instance, the LLRs required for the matrix processing for the row R1 are data pieces that correspond to valid blocks H(1,2), H(1,4), and H(1,Ck+2), which are non-zero blocks in the row R1.

Subsequently, the same process will be repeated.

A control of the control section 15-1 includes transferring the LLRs required for the matrix processing for each row of the matrix blocks from the LMEM 12A to the LREG 4, executing a calculating process by the LREG 4 and the calculating section 13A, writes the updated LLRs being the calculating result back from the LREG 4 to the LMEM 12A via the multiplexer 2 and the rotator 3.

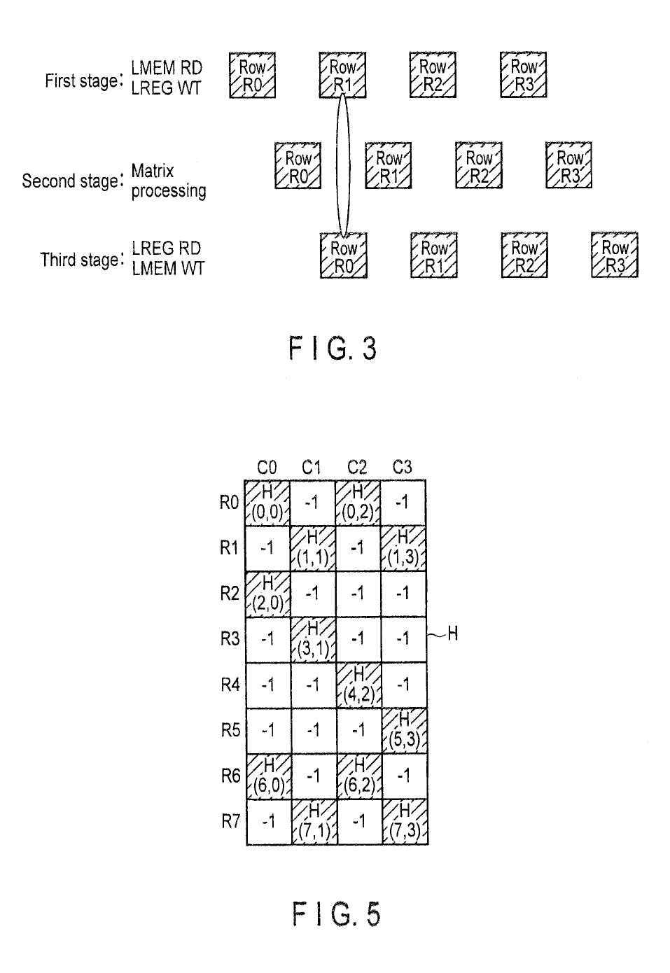

FIG. 3 is a timing chart illustrating an example of a process of the error correction decoder 1 according to this embodiment. The error correction decoder 1 successively executes a first through a third stage.

In FIG. 3, the third stage for the row R0 and the first stage for the row R1 are executed in parallel. The third stage for the row R1 and the first stage for the row R2 are executed in parallel. Thus, in FIG. 3, the third stage for a certain row is executed in parallel with the first stage for a next row.

In the first stage, the LLRs required for the certain row are read out from the LMEM 12A and are stored in the LREG 4. That is, in the first stage, the LLRs required for the certain row are transferred from the LMEM 12A to the LREG 4.

In the second stage, the calculating section 13A executes the matrix processing by the check-node based parallel process mode based on the LLRs of the LREG 4.

In the third stage, when the matrix processing for the LLRs of the LREG 4 are terminated, the updated LLRs are read out from the LREG 4 and are written in the LMEM 12A. That is, in the third stage, the updated LLRs are transferred from the LREG 4 to the LMEM 12A.

The third stage for the certain row is executed in parallel with the first stage for the next row. A writing back process of the third stage in the matrix processing applied to the certain row will be executed several cycles earlier than the first stage in the matrix processing applied to the next row. After the writing back process from the LREG 4 to the LMEM 12A of the matrix processing for the certain row is terminated, the LLRs required for the matrix processing for the next row are read out from the LMEM 12A, and are written to empty state addresses of LREG4.

When reading out of a certain LLR from the LMEM 12A and writing of the certain LLR in the LMEM 12A collide with each other, the certain LLR is not read out from the LMEM 12A, but the certain LLR written in the LREG4 is read out and rewritten in the LREG4. Thus, when the reading out from the LMEM 12A and the writing in the LMEM 12A collide with each other for the same LLR, the reading out of the same LLR from the LMEM 12A is stopped and the same LLR written in the LREG4 is used. This operation is called a by-pass process. More specifically, when accesses for the same address of the LMEM 12A based on the writing back from the LREG 4 to the LMEM 12A for the row R0 and the reading out from the LMEM 12A to the LREG 4 for the row R1 are simultaneously generated (an LLR access collision) in FIG. 3, for instance, the LLR used for the Row R1 is temporarily read out from the LREG 4 and is rewritten to the LREG 4.

In the error correction decoder 1 according to this embodiment, the number of variable nodes used for a process each of the rows R0-Rn is determined by a row weight for each row. In the case of LDPC, a code design approach where the row weight is fixed and the data length is changed is frequently used. An application of the code design approach makes it possible to maintain a specific decoding characteristic even if the row weight is not made large in proportion to the data length. For instance, it is determined that a setting of the data length being 1 Kbyte and the row weight being 32 is changed to a setting of the data length being enlarged to be 4 Kbytes and the row weight remaining 32. In this case, the longer the data length is made, the smaller a memory capacity of the LREG 4 for a memory capacity of the LMEM 12A can be made. For instance, when the data length is 1 Kbyte and the memory capacity of the LREG 4 for the memory capacity of the LMEM 12A is 50%, the data length may be 4 Kbyte and the memory capacity of the LREG 4 for the memory capacity of the LMEM 12A may be 12.5%.

A LDPC decoder of the normal check-node based parallel process mode includes a register for a purpose of providing the LMEM with multiple ports. Therefore, the longer corrected data is, the larger a circuit scale of the LMEM may be.

In contrast, the longer the data is, the larger a circuit scale reduction effect may be in this embodiment, since the LREG 4 is used for a cache memory of the LMEM 12A.

This embodiment makes it possible to improve the decoding characteristic, a quickness, and a cost performance.

In this embodiment, a size of the LREG 4 used as a cache memory may change in accordance with the row weight. The row weight does not depend on the data length. Therefore, this embodiment prevents the control from becoming complicated.

### Second Embodiment

A modification of the aforementioned first embodiment will be explained below as this embodiment. In this embodiment, the LREG 4 is multiplied and includes a LREG 401 and LREG 402. In this embodiment, a case where the LREG 4 includes two LREGs 401, 402 will be explained as an example. However, it may be possible that the LREG 4 includes three or more LREGs.

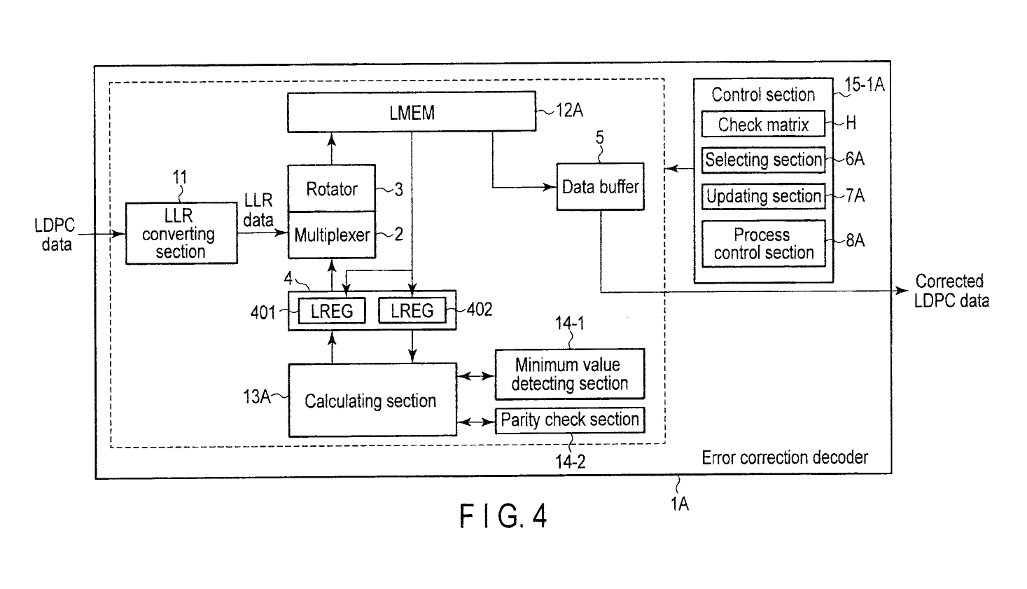

FIG. 4 is a block diagram illustrating an example of a schematic structure of an error correction decoder 1A according to this embodiment.

The LREG 4 of the error correction decoder 1A includes LREG 401 and LREG 402, and is multiplied. In this embodiment, each time a processed row is changed, the LREG 401 or the LREG 402 used for the processed row is alternately switched.

A selecting section 6A of a control section 15-1A stores the LLRs selected from the LMEM 12A and corresponding to each row of matrix blocks while switching a memory destination between the LREG 401 and the LREG 402.

An updating unit 7A writes the updated LLRs back to the LMEM 12A via the multiplexer 2 and the rotator 3 while switching between the LREG 401 and the LREG 402.

A process control section 8A causes the calculating section 13A to execute a calculating process while switching between the LREG 401 and the LREG 402 to which the calculating section 13A executes reading out and writing.

FIG. 5 is a view illustrating an example of a check matrix H according to this embodiment. In the check matrix H, the number of rows and the number of columns of the matrix blocks can be suitably changed.

In FIG. 5 of the matrix blocks, matrix blocks described by diagonally shaded blocks such as H(0,0) are non-zero matrices (or valid blocks). In FIG. 5, matrix blocks specified as −1 are zero matrices (or invalid blocks). The check matrix H has a constraint in which the matrix blocks of the non-zero matrices are not successively arranged in the same column. For instance, it is define that Z is a least number of the zero matrices being present between two adjacent non-zero matrices in a column direction, the number z of the LLRs in FIG. 5 may be represented by Z=1.

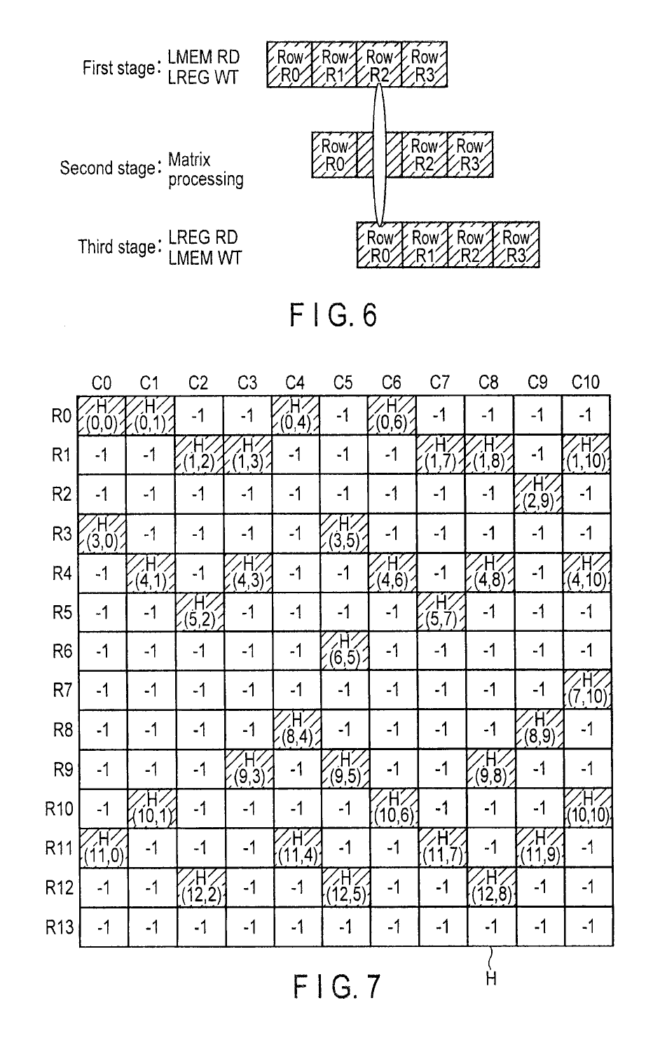

FIG. 6 is a timing chart illustrating an example of a process of the error correction decoder 1A according to this embodiment.

In FIG. 6, the second stage for the row R0 and the first stage for the row R1 are processed in parallel. The third stage for the row R0, the second stage for the row R1, and the first stage for the row R2 are processed in parallel. Thus, in FIG. 6, the first stage through the third stage are consecutively executed to each of the rows R0-R3. Furthermore, processes of each of the first, the second and the third stage process are consecutively executed to each of the rows R0-R3.

However, in this embodiment, when reading out from the LMEM 12A and writing in the LMEM 12A collide with each other for the same LLR of the LMEM 12A, the by-pass process which reads out the LLR from the LREG 4 and rewrites the LLR to the LREG 4 is executed.

As described above, in this embodiment, multiplexing is implemented by the LREG 401 and the LREG 402, and at least Z=1 matrix block of the zero matrix is inserted between the matrix blocks of the non-zero matrices in the column direction of the check matrix H. Thus, the first stage through the third stage can consecutively execute, and it is possible to prevent increase in overhead of a transmitting process between the LMEM 12A and the LREG 4 in comparison with the normal check-node based parallel process mode.

### Third Embodiment

In this embodiment, a modification example of the error correction decoder 1A according to the second embodiment will be explained below. This embodiment explains a check matrix H in which the minimum number z of the zero matrices being present between the non-zero matrices in the column direction is 2 or more.

FIG. 7 is a drawing illustrating an example of a check matrix H according to this embodiment. In the check matrix H, the number of rows and the number of columns can be suitably changed.

In the check matrix H of FIG. 7, the zero matrices of at least Z=2 in number are inserted between the non-zero matrices in the same column.

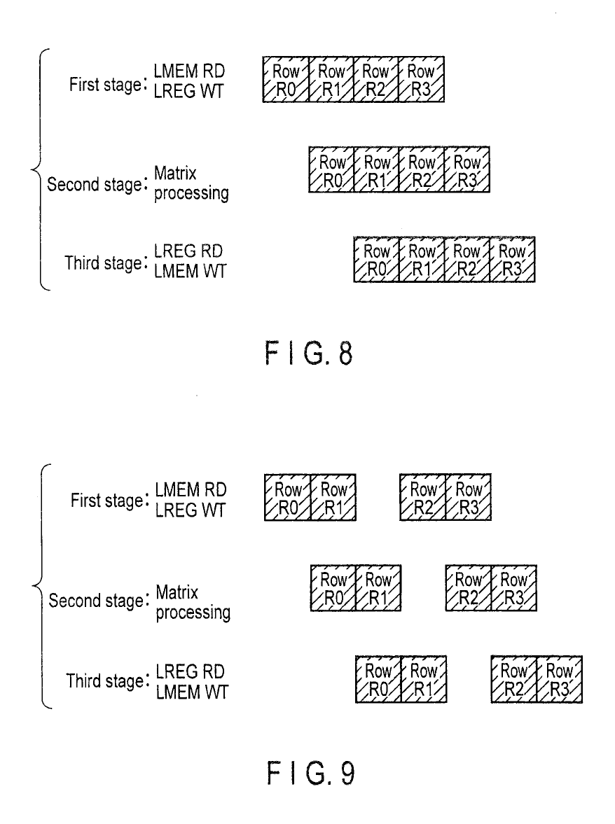

FIG. 8 is a timing chart illustrating an example of a process of the error correction decoder 1A according to this embodiment.

In FIG. 8, the first stage through the third stage are successively executed to each of the rows R0-R3. Furthermore, processes of each of the first through the third stage are successively executed to each of the rows R0-R3.

When the check matrix H according to this embodiment is used, it is possible to avoid a collision between the reading from the LMEM 12A and the writing in the LMEM 12A for the LLR as explained in the first and the second embodiment. Therefore, there is no need to execute the by-pass process, so that the control by the control section 15-1 can be simplified and efficient.

### Fourth Embodiment

In this embodiment, a modification example of the error correction decoder 1A according to the second and third embodiment will be explained below. In this embodiment, a check matrix H includes a portion in that the non-zero matrices are successively arranged, and processes in the first stage through the third stage corresponding to the non-zero matrices are not successively executed.

FIG. 9 is a timing chart illustrating an example of a process of the error correction decoder 1A according to this embodiment.

In this embodiment, It is assumed that the check matrix H does not partly satisfy the constraint of being Z=1 or more. FIG. 9 illustrates that successive non-zero matrices in the column direction are present between the row R1 and the row R2.

Thus, in the case where the successive non-zero matrices in the column direction are present between the row R1 and the row R2, an idle cycle is inserted between the first stage though the third stage for the row R1 and the first stage though the third stage for the row R2, and an adjustment of the pipeline process is executed. In FIG. 9, the process control section 8A serially executes the pipeline process between row R1 process and row R2 process.

For example, there may arise a case where it is difficult for a parity portion of the check matrix H to satisfy the constraint of being Z=1 or more. Thus, in this embodiment, the pipeline process is canceled when the parity portion of the check matrix H is processed.

As described above, in this embodiment, even if the check matrix H includes a portion that do not satisfy the constraint of being Z=1 or more, the pipeline process is executed for a portion that satisfy the constraint of being Z=1 or more, and thus increase of a process speed is achieved.

### Fifth Embodiment

The normal check-node based parallel process mode and its modified mode will be explained below as this embodiment. The error correction decoder 1, 1A in any one of the first through the fourth embodiment have a structure that the LDPC decoder of the normal check-node based parallel process mode explained below implements the multiplexer 2, the rotator 3, the LREG 4, the selecting unit 6 or 6A, the updating unit 7 or 7A, and the process control unit 8 or 8A.

### <<Explanation of Check-Node Based Parallel Process Mode>>

Referring to FIG. 1 to FIG. 5C, a basic operation of the LDPC is explained.

### (LDPC Code and Partial Parallel Process)

To begin with, a description is given of a LDPC code and a partial parallel process in this embodiment. The LDPC code is a linear code which is defined by a very sparse check matrix, that is, a check matrix in that a number of non-zero elements in the matrix is a small, and can be represented by a Tanner graph. An Error correction process corresponds to updating by exchanging locally estimated results between variable nodes, which correspond to bits of a code word, and check nodes corresponding to respective parity check formulae, the variable nodes and the check nodes being connected on the Tanner graph.

FIG. 10 is a view illustrating an example of a check matrix of LDPC.

FIG. 10 shows a check matrix H1 with a row weight wr=3 and a column weight wc=2 in a (6, 2) LDPC code. The (6, 2) LDPC code is a LDPC code with a code length of 6 bits and an information length of 2 bits.

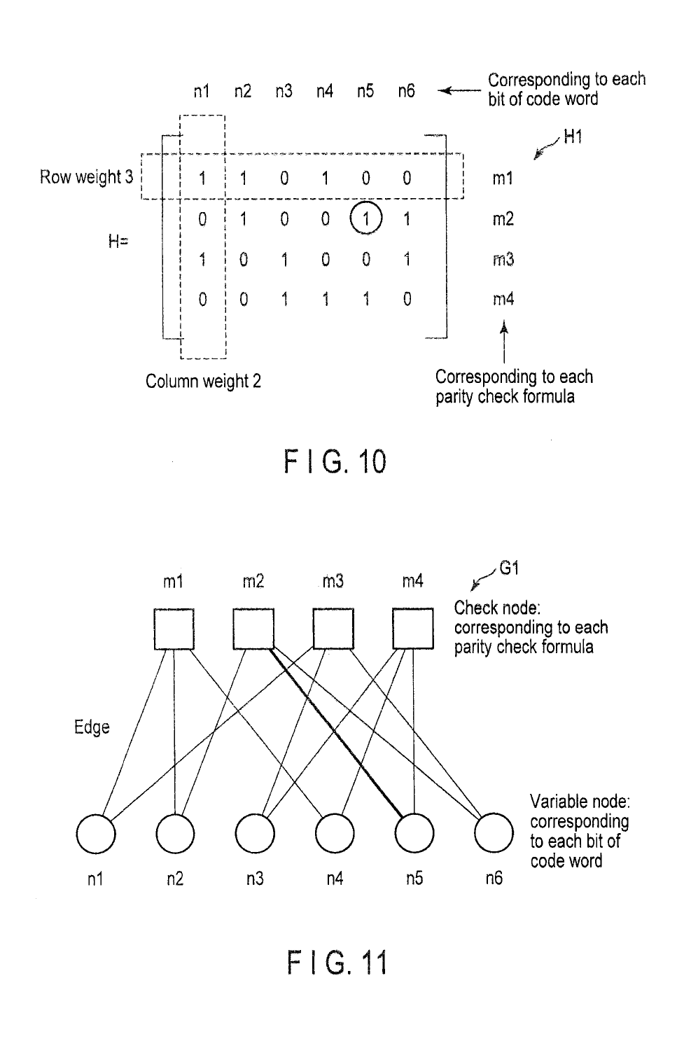

FIG. 11 is a view illustrating an example of the check matrix represented as a Tanner graph.

When the check matrix H1 is represented by a Tanner graph G1, the variable nodes correspond to columns of the check matrix H1, and check nodes correspond to rows of the check matrix H1. Of the elements of the check matrix H1, nodes of “1” are connected by edges, whereby the Tanner graph G1 is formed. For example, “1”, which is encircled at a second row and a fifth column of the check matrix H1, corresponds to an edge which is indicated by a thick line in the Tanner graph G1. In addition, the row weight wr=3 of the check matrix H1 corresponds to the number of variable nodes which are connected to one check node, namely an edge number “3”, and the column weight wc=2 of the check matrix H1 corresponds to the number of check nodes which are connected to one variable node, namely an edge number “2”.

Decoding of LDPC encoded data is executed by repeatedly updating reliability (probability) information, which is allocated to the edges of the Tanner graph, at the nodes. The reliability information is classified into two kinds, i.e. probability information from a check node to a variable node (hereinafter also referred to as “external value” or “external information”, and expressed by symbol “α”), and probability information from a variable node to a check node (hereinafter also referred to as “prior probability”, “posterior probability”, simply “probability”, or “logarithmic likelihood ratio (LLR)”, and expressed by symbol “β” or “λ”). A Reliability update process includes a row process and column process. A unit of execution of a single row process and a single column process is referred to as “1 iteration (round) process”, and a decoding process is executed by a repetitive process in which the iteration process is repeated.

As described above, the external value α is the probability information from the check node to the variable node at a time of an LDPC decoding process, and the probability β is the probability information from the variable node to the check node.

In a semiconductor memory device, threshold determination information is read out from a memory cell which stores encoded data. The threshold determination information includes a hard bit (HB) which indicates whether stored data is “0” or “1”, and a plurality of soft bits (SB) which indicate the likelihood of the hard bit. The threshold determination information is converted to LLR data by the LLR table which is prepared in advance, and becomes initial LLR data of the iteration process.

The decoding process by a parallel process can be executed in a reliability update algorithm (decoding algorithm) for variable nodes and check nodes, with use of a sum product algorithm or a mini-sum product algorithm.

However, in the case of LDPC encoded data with a large code length, a complete parallel process, in which all processes are executed in parallel, is not practical since many calculating circuits need to be implemented.

By contrast, if a check matrix, which is formed by combining a plurality of matrix blocks (unit blocks), is used, a circuit scale can be reduced by executing a partial parallel process by calculating circuits corresponding to a variable node number P when a block size is p.

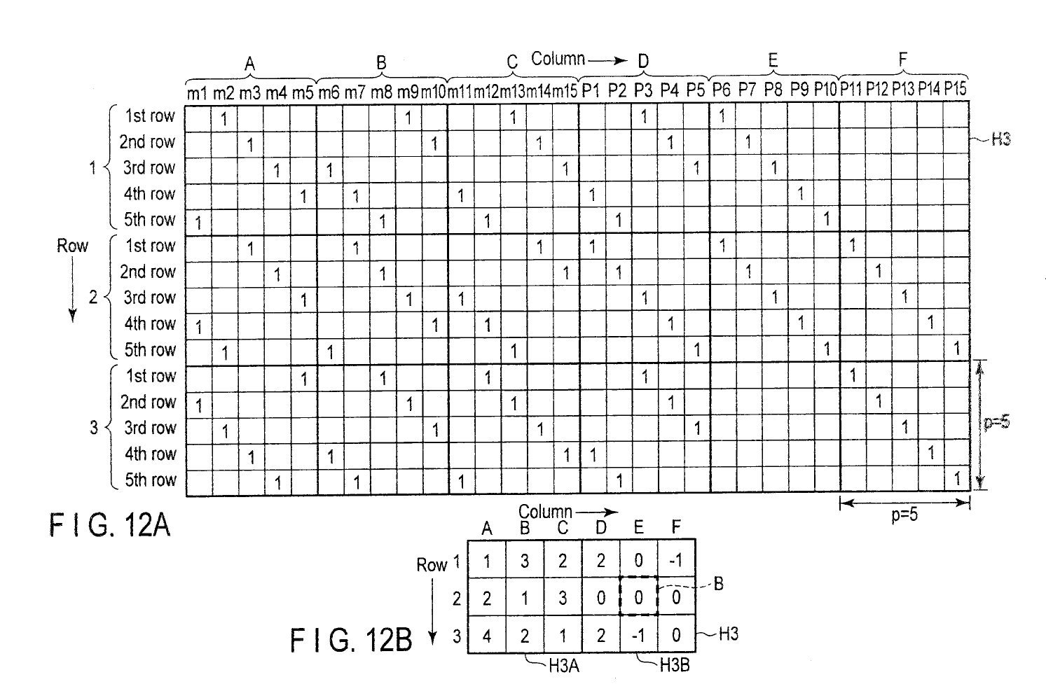

FIG. 12A is a view illustrating an example of a check matrix composed by combining a plurality of matrix blocks.

A check matrix H3 of FIG. 12A includes 15 rows in the vertical direction and 30 columns in the horizontal direction, by arranging 6 matrix blocks, each comprising 5×5 elements, in the horizontal direction and three matrix blocks in the vertical direction.

FIG. 12B is a view illustrating an example of shift values of diagonal components of the matrix blocks.

As illustrated in FIG. 12B, each matrix block B of the check matrix H3 is a square matrix. The square matrix (hereinafter referred to as “shift matrix”) is obtained by shifting a unit matrix including is arranged in diagonal components and Os in other components by a degree corresponding to a numerical value.

The check matrix H3 shown in FIG. 12A includes an encode-target (message) block portion H3A, which is matrix blocks for user data, and a parity block portion H3B for parity, which is generated from the user data.

As shown in FIG. 12B, a shift value “0” indicates a unit matrix, and a shift value “−1” indicates a zero matrix. Since the zero matrix requires no actual calculating process, a description of the zero matrix is omitted in a description below.

A bit, which is shifted out of a block by a shift process, is inserted in a leftmost column in the matrix block. In the decoding process using the check matrix H3, necessary matrix block information, that is, information of nodes to be processed, can be obtained by designating a shift value. In the check matrix H3 including matrix blocks each with 5×5 elements, the shift value is any one of 0, 1, 2, 3 and 4, except for the zero matrix which has no direct relation to the decoding process.

In the case of using the check matrix H3 in which square matrices each having a block size 5×5 (hereinafter referred to as “block size 5”) shown in FIG. 12A are combined, five calculating circuits are provided in the calculating section, and thereby the partial parallel process can be executed for the five check nodes. In order to execute the partial parallel process, a variable node memory section (LMEM), which stores a variable (hereinafter referred to as “LMEM variable” or “LLR”) for finding a prior/posterior probability β in units of a variable node, and a check node memory section (TMEM), which stores a variable (hereinafter referred to as “TMEM variable”) for finding an external value α in units of a check node, are necessary. Since the variable nodes are managed by column-directional addresses (column addresses), the LMEM is managed by the column addresses. Since the check nodes are managed by row-directional addresses (row addresses), the TMEM is managed by row addresses. When the external value α and the probability β are calculated, the LMEM variable, which is read out from the LMEM, and the TMEM variable, which is read out from the TMEM, are delivered to the calculating circuits, and the calculating processes are executed.

When the decoding process is executed by using the check matrix H3 which is formed by combining a plurality of matrix blocks, if plural TMEM variables, which are read out from the TMEM, are rotated by a rotater 113A in accordance with shift values, there is no need to store the entirety of the check matrix H3.

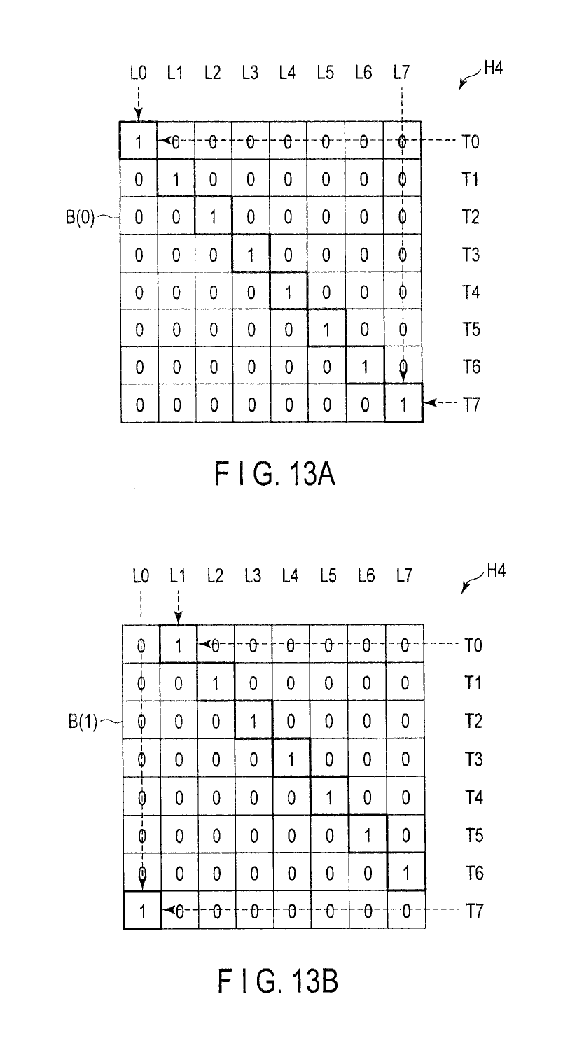

FIG. 13A and FIG. 13B are respectively views illustrating examples of matrix blocks of shift values 0, 1.

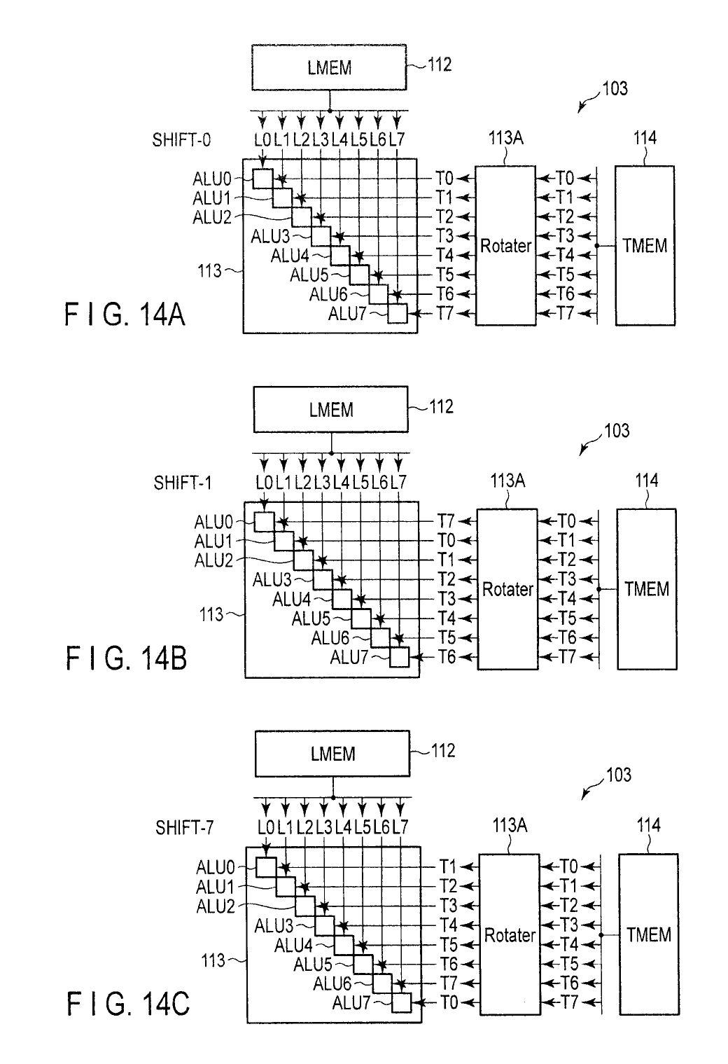

FIG. 14A to FIG. 14C are views illustrating a first through a third example of processes based on TMEM variables.

For example, as illustrated in FIGS. 13A and 13B and FIGS. 14A, 14B and 14C, when a process for eight TMEM variables which are read out from the TMEM 114 is executed by using a check matrix H4 of a block size 8, a memory controller 103 uses the LMEM 112, TMEM 114, calculating section 113 and rotater 113A. The calculating section 113 includes eight calculating circuits ALU0 to ALU7, and eight processes can be executed in parallel. The shift values in the case of using the check matrix H3 of the block size 8 are eight kinds, i.e. 0 to 7.

As illustrated in FIG. 13A and FIG. 14A, in the case of a block B(0) with a shift value “0”, a rotate process of a rotate value “0” is executed by the rotater 113A, and a calculation is performed between variables of the same address. It should be noted that the rotate process with the rotate value “0” means that no rotation is executed.

LMEM variable of column address 0, TMEM variable of row address 0 (indicated by a broken line in FIG. 13A);

LMEM variable of column address 1, TMEM variable of row address 1;

LMEM variable of column address 2, TMEM variable of row address 2;

.

.

.

LMEM variable of column address 7, TMEM variable of row address 7 (indicated by a broken line in FIG. 13A).

On the other hand, as shown in FIG. 13B and FIG. 14B, in the case of a block B(1) with a shift value “1”, a rotate process of a rotate value “1” is executed by the rotater 113A, and a calculation is performed between variables as described below. Specifically, the rotate process with the rotate value “1” is the shift process in which each variable is shifted to the right by one, and the variable of a lowermost row, which has been shifted out of the block, is inserted in the lowermost row on a left side.

LMEM variable of column address 0, TMEM variable of row address 7 (indicated by a broken line in FIG. 13B);

LMEM variable of column address 1, TMEM variable of row address 0 (indicated by a broken line in FIG. 4B);

LMEM variable of column address 2, TMEM variable of row address 1;

.

.

.

LMEM variable of column address 7, THEM variable of row address 6.

As illustrated in FIG. 14C, in the case of a block B(7) with a shift value “7”, a rotate process of a rotate value “7” is executed by the rotater 113A, and a calculation is performed between variables as described below. Specifically, the rotate process with the rotate value “7” is the shift process in which the rotate process with the rotate value “1” is executed seven times.

LMEM variable of column address 0, THEM variable of row address 1;

LMEM variable of column address 1, TMEM variable of row address 2;

LMEM variable of column address 2, THEM variable of row address 3;

.

.

.

LMEM variable of column address 7, TMEM variable of row address 0.

As has been described above, the rotater 113A rotates variables read out from the LMEM 112 or TMEM 114 based on a rotate value corresponding to the shift value of the matrix block before the variables are provided for the calculating section 113. In the case of the memory controller 103 using the check matrix H3 of the block size 8, the maximum rotate value of the rotater 113A is “7” that is “block size −1”. If the quantifying bit number of reliability is “u”, the bit number of each variable is “u”. Thus, an input/output data width of the rotater 113A is “8×u” bits.

The LMEM that stores LLR data, which represents a likelihood of data read out from the NAND type flash memory by quantizing the likelihood by 5 to 6 bits, needs to have a memory capacity which corresponds to a code length×a quantizing bit number. From a standpoint of an optimization of a cost, the LMEM functioning as a large-capacity memory is necessarily implemented with an SRAM. Accordingly, a calculating algorithm and hardware of the LDPC decoder for the NAND type flash memory are optimized, in general, on a presupposition of the LMEM that is implemented with the SRAM. As a result, a unit block based parallel mode, in which the LLR data are accessed by sequential addresses, is generally used as the LDPC decoder.

However, the unit block based parallel mode has a complex calculating algorithm, and requires a plurality of rotaters of a large-scale logic (large-scale wiring areas). A provision of plural rotaters poses a difficulty in increasing the degree of parallel process and the process speed.

(Unit Block Based Parallel Mode)

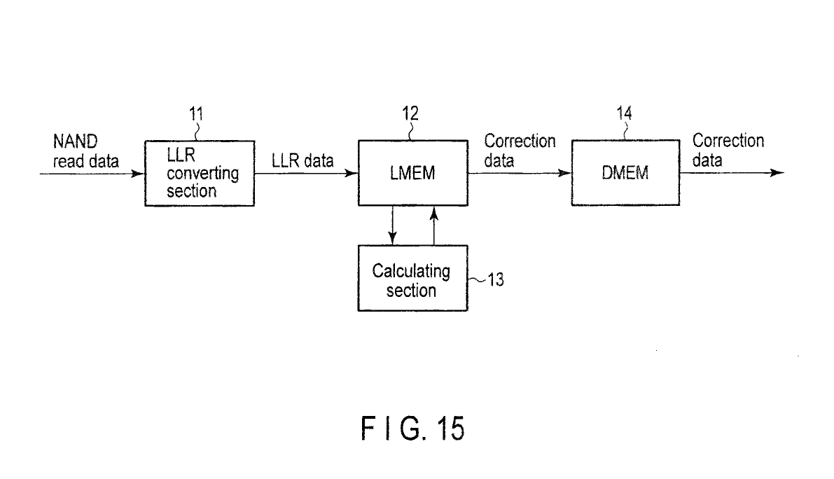

Referring to FIG. 15 to FIG. 17, the unit block based parallel mode is described.

FIG. 15 is a view illustrating an example of a configuration of an LDPC decoder.

In order to simplify a description, it is assumed that a check matrix is one row×three columns, a block size is 4×4, a code length is 12 bits (hereinafter, the code length is referred to as “data length”), and four check nodes are provided per row. It is assumed that the row weight is “3” and the column weight is “1”.

As illustrated in FIG. 15, LDPC data read out from the NAND type flash memory, is divided with a unit block size from a beginning of data, that is, with four bits, and provided for the LLR conversion section 11. In the LLR conversion section 11, LLR data converted by using the LLR converting table is stored in an LMEM 12.

The calculating section 13 reads LLRs of matrix blocks from the LMEM 12, executes a calculating operation on the LLRs, and writes the LLRs back into the LMEM 12. The calculating section 13 includes the calculating sections 13 corresponding to the matrix block size (i.e. corresponding to four variable nodes). In this example, a data length is 12 bits and is short. However, for example, if the data length increases to as large as 10 Kbits, because of an address management of the LMEM 12, an architecture is adopted that LLRs of variable nodes with sequential addresses are accessed together from the LMEM 12 and the accessed LLRs are subjected to calculating operations. When the LLRs of variable nodes with sequential addresses are accessed together, the LLRs are accessed in units of a base block and the process is executed (“unit block parallel mode”). At this time, in order to programmably select 4 variable nodes belonging to a basic block connected to a check node, the above-described rotater 113A is provided.

The rotater 113A includes a function of arbitrarily selecting four 6-bit LLRs with respect to a certain check node, if the quantizing bit number is 6 bits. Since the block size of an actual product is, e.g. 128×128 to 256×256, the circuit scale and wiring area of the rotater 113A become enormous.

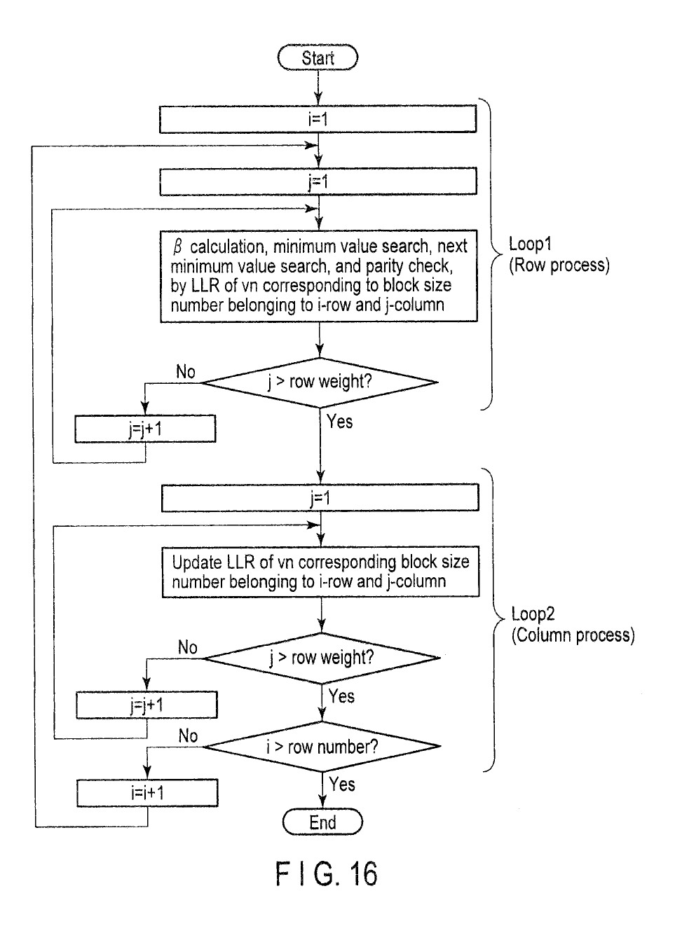

FIG. 16 is a flowchart illustrating an example of an operation of the LDPC decoder shown in FIG. 15. FIG. 16 illustrates a process flow of the unit block based parallel mode. As illustrated in FIG. 16, the unit block based parallel mode is executed by dividing the row process and column process into 2 loops. In loop 1, β is found by subtracting a previous α from the LLR that is read out from the LMEM 12, a minimum α1 and a next minimum α2 are found from β connected to the same check node, and these are temporarily stored in an intermediate-value memory 15-2. In addition, β found in loop 1 is once written back into the LMEM 12. A parallel process is executed for four variable nodes at a time, and the parallel process is repeatedly executed three times, which correspond to the row weight, in a process of one row. Thereby, α1 and α2 are calculated.

In loop 2, β is read out from the LMEM 12, α1 or α2 calculated in the loop 1, are added to the read-out β, and a resultant is written back to the LMEM 12 as a new LLR. This operation is executed in parallel for four variable nodes at a time, and the parallel process is repeatedly executed three times for the process of one row. Thereby, an update of LLRs of all variable nodes is completed.

By executing processes of the loop 1 and loop 2 for one row, one iteration (hereinafter also referred to as “ITR”) is finished. At a stage at which 1 ITR is finished, if the parity of all check nodes passes, correction processing is successfully finished. If the parity is NG, the next 1 ITR is executed. If the parity fails to pass even if ITR is executed a predetermined number of times, the correction processing terminates in failure.

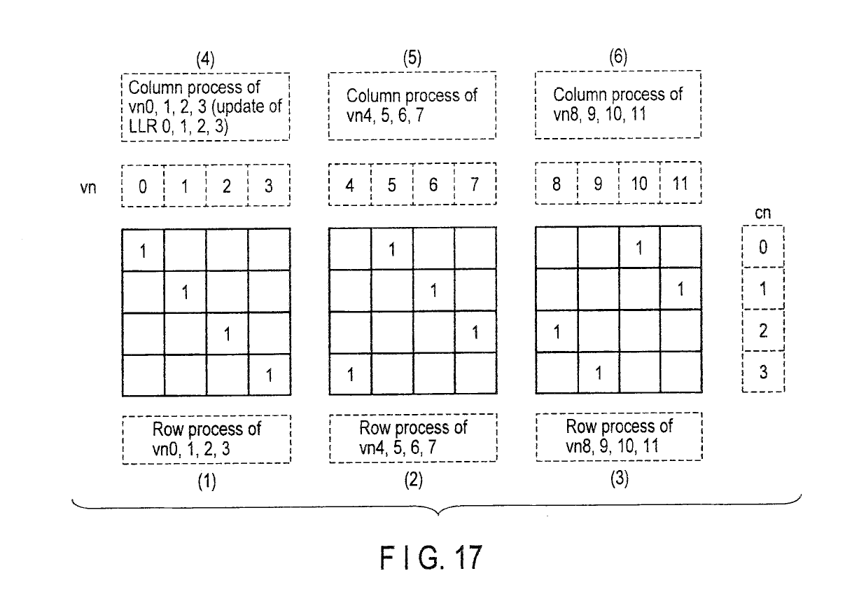

FIG. 17 is a view illustrating an example of a procedure for updating LLR corresponding to the variable nodes.

(1) Row process of variable nodes vn0, 1, 2 and 3 belonging to column block 0 (calculation of β, α1 and α2 and parity check of check nodes cn0, 1, 2, 3)
(2) Row process of variable nodes vn4, 5, 6, 7 belonging to column block 1.
(3) Row process of variable nodes vn8, 9, 10, 11 belonging to column block 2.
(4) Column process of variable nodes vn0, 1, 2, 3 belonging to column block 0 (LLR update).
(5) Column process of variable nodes vn4, 5, 6, 7 belonging to column block 1.
(6) Column process of variable nodes vn8, 9, 10, 11 belonging to column block 2.

A process efficiency of the above-described unit block parallel mode is low, since LLR update processes for all variable nodes are not completed unless the column process and row process are executed by different loops. An essential reason for this is that a retrieval process of the LLR minimum value of variable nodes belonging to a certain check node, and a retrieval process of the next minimum value cannot be executed at the same time as the LLR update process. As a result, a circuit scale increases, power consumption increases, and a cost performance deteriorates.

In addition, in order to access LLRs of variable nodes of one block, it is necessary to access the large-capacity LMEM 12 each time, and the power consumption by the LMEM 12 increases. Since the LMEM 12 is constructed by the SRAM, a power is consumed not only at a time of write but also at a time of read.

Furthermore, since the LMEM 12 is read twice and written twice, the power consumption increases.

Besides, an LDPC decoder for a multilevel (MLC) NAND type flash memory, which stores data of plural bits in one memory cell, is designed on a presupposition of a defective model in which a threshold voltage of a cell shifts. Thus, such an error (hereinafter referred to as “hard error (HE)”) is not assumed that a threshold voltage shifts beyond 50% of an interval between threshold voltages, or the threshold voltage shifts beyond a distribution of neighboring threshold voltages. If such the error occurs frequently, a correction capability lowers. The reason for this is that since a threshold voltage at a time of read does not necessarily exist near a boundary of a determination area, such a case occurs that the logarithmic likelihood ratio absolute value (|LLR|), which is an index of likelihood of a determination result of the threshold voltage, increases, despite the data read being erroneous.

(First Mode of Check-Node Based Parallel Process)

In a first mode of the check-node based parallel process, an efficiency of a calculating process is improved, a cost performance is improved, and a degradation of a correction capability by a hard error is improved.

The first mode of the check-node based parallel process includes the LMEM 12A storing the LLR data obtained by converting the LDPC data by the LDPC decoder for the NAND type flash memory, configures the check matrix by M*N matrix blocks with M rows and N columns, includes a calculating section executing an LLR update process by a pipeline-process (a variable node process of the check node base) for the variable nodes which are connected to a selected check node, includes a calculating section executing the variable node process of some check nodes by a parallel process, and can executes the variable node process per 1 check node by one cycle at a time of the parallel process.

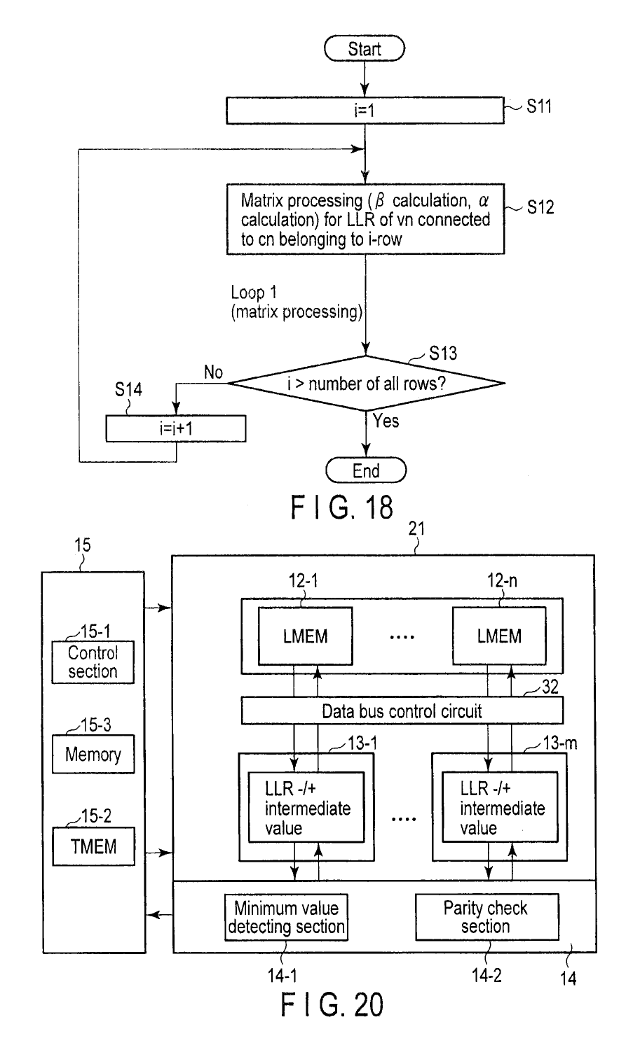

FIG. 18 to FIG. 22 illustrate the first mode of the check node based parallel process. The check matrix is the same as described above. The check matrix is 1 row×3 columns. A block size is 4×4. 4 check nodes are provided per row. The row weight is “3”, and the column weight is “1”.

FIG. 18 is a flowchart illustrating an example of an operation of the first mode of the check-node based parallel process. The check-node based parallel process of the first mode is characterized by simultaneous execution of a row process and a column process in a single loop. In the example shown in FIG. 17 explained above, the LLRs of variable nodes with sequential addresses are read out from the LMEM 12.

On the other hand, in the first mode, all variable nodes, which are connected to a check node, are simultaneously read out. Specifically, the LLRs of variable nodes, which are connected to the check node belonging to i=1 row, are read out from the LMEM 12A, and matrix processing is executed. In the first mode, a β calculating operation and an α calculating operation are simultaneously executed (step S11, S12). Then, a value of row “i” is incremented, and a process of step S12 is executed for all the number of rows (step S13, S14, S12).

The first mode differs from the example of FIG. 17 with respect to the structure of the LMEM 12A, since all variable nodes, which are connected to the check node, are simultaneously read out.

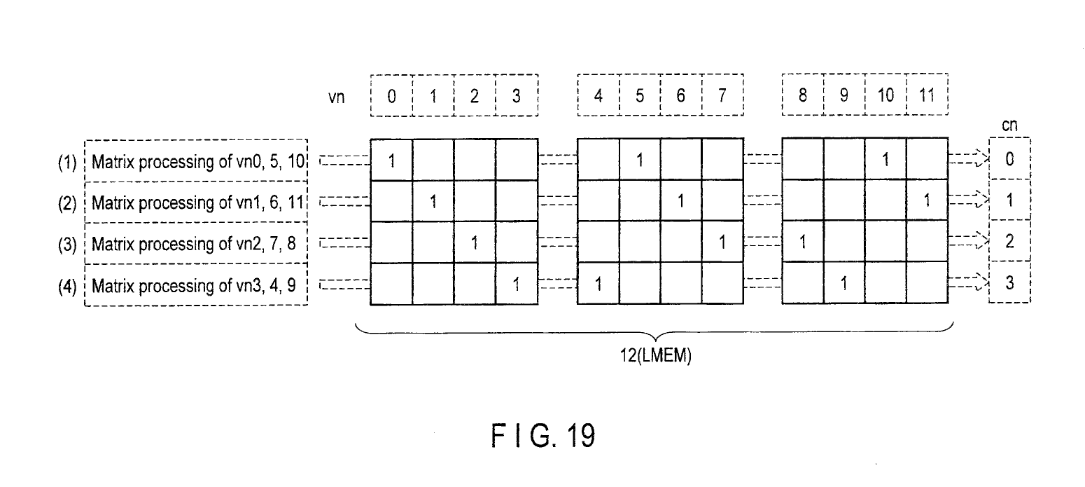

FIG. 19 is a view illustrating an example of a concept of the LMEM 12A according to the first mode.

As illustrated in FIG. 19, the LMEM 12 is composed of, for example, three modules, or a memory including three ports. In this case, independent addresses of three systems can be provided for the LMEM 12, and three unique variable nodes can be accessed. For example, the LLRs of 3 variable nodes are simultaneously read out from the LMEM 12.

In the case where the LMEM 12 is composed of a single module, as shown in FIG. 17, memory addresses of variable nodes on the LMEM 12 become non-sequential. By contrast, in the case where the LMEM 12 is composed of three modules or a memory including three ports, as shown in FIG. 19, independent addresses of three systems can be input to the LMEM 12, and three unique variable nodes can be accessed. As illustrated in FIG. 19, the update procedure of the variable node is as follows.

(1) Matrix processing (LLR update) of variable nodes vn0, 5, 10 connected to a check node cn0
(2) Matrix processing (LLR update) of variable nodes vn1, 6, 11 connected to a check node cn1
(3) Matrix processing (LLR update) of variable nodes vn2, 7, 8 connected to a check node cn2
(4) Matrix processing (LLR update) of variable nodes vn3, 4, 9 connected to a check node cn3.

In the first mode, with substantially the same circuit scale as in the prior art, about 1.5 times to 2 times higher speed can be achieved, and the cost performance can greatly be improved.

The decoding algorithm of the first mode becomes the same as in the example of FIG. 17, for a following reason.

In the case of the first mode, the order of update of LLRs is different from the example of FIG. 17, but the first mode is the same as the prior art in that the update of all LLRs is finished at a stage when the row process/column process for one row has been finished.

Specifically, as illustrated in FIG. 17, in the case where the check matrix is formed by the unit block mode, a certain variable node is not connected to plural check nodes in a single row. Thus, there occurs no row process using an LLR which has just been updated during a process of a certain row.

FIG. 20 is a block diagram illustrating an example of a schematic structure of an LDPC decoder according to the first mode. In FIG. 20, the LLRs of a plurality of variable nodes, which are connected to one check node, are processed. FIG. 20 illustrates an example of implementation in which a degree of parallel process is “1” (cp=1).

In FIG. 20, an LDPC decoder 21 includes a plurality of LMEMs 12-1 to 12-n, a plurality of calculating sections 13-1 to 13-m, a row-directional logic circuit 14, a column-directional logic circuit 15 which controls these components, and a data bus control circuit 32. The row-directional logic circuit 14 includes a minimum value detection section 14-1, and a parity check section 14-2. The column-directional logic circuit 15 includes a control section 15-1, the intermediate-value memory 15-2 such as the TMEM, and a memory 15-3.

The LMEMs 12-1 to 12-n are configured as modules for respective columns. The number of LMEMs 12-1 to 12-n, which are disposed, is equal to the number of columns. Each of the LMEMs 12-1 to 12-n is implemented with, for example, a block size×6 bits.

The calculating sections 13-1 to 13-m are arranged in accordance with not the number of columns but the row weight number m. The number of matrix blocks (non-zero blocks), in which a shift value is not “0”, corresponds to the row weight number. Specifically, since the LLR of one variable node is read out from one non-zero block, it should suffice if the number of the calculating sections is m.

The data bus control circuit 32 executes dynamic allocation as to which of LLRs of variable nodes of column blocks is to be taken into which of the calculating sections 13-1 to 13-m, according to which of ordered rows is to be processed by the calculating sections 13-1 to 13-m. By this dynamic allocation, a circuit scale of the calculating sections 13-1 to 13-m can be reduced.

The column-directional logic circuit 15 includes, for example, the control section 15-1, the intermediate value memory 15-2 such as the TMEM, and the memory 15-3. The control section 15-1 controls an operation of the LDPC decoder 21, and may be composed of a sequencer.

The intermediate value memory 15-2 stores intermediate value data, for instance, α (α1, α2) of ITR, a sign of α of each variable node (sign information of α, which is added to all variable nodes connected to the check node), INDEX, and a parity check result of each check node. The α sign of each variable node will be described later.

The memory 15-3 stores, for example, the check matrix and an LLR conversion table described later.

The control section 15-1 provides variable node addresses to the LMEM 12-1 to LMEM 12-n in accordance with a block shift value. Thereby, LLRs of variable nodes corresponding to the weight number of the row, which is connected to the check node, can be read out from the LMEM 12-1 to LMEM 12-n.

The minimum value detection section 14-1, which is included in the row-directional logic circuit 14, retrieves, from the calculating results of the calculating sections 13-1 to 13-m, the minimum value and next minimum value of the absolute values of the LLRs connected to the check node. The parity check section 14-2 checks the parity of the check node. The LLRs of all variable nodes, which are connected to the read-out check node, are supplied to the minimum value detection section 14-1 and parity check section 14-2.

The calculating sections 13-1 to 13-m generate β (logarithmic likelihood ratio) by calculation based on the LLR data read out from the LMEMs 12-1 to 12-n, an intermediate value, for instance, α (α1 or α2) of the previous ITR, and the sign of a of each variable node, and further calculates updated LLR′ based on the generated β and the intermediate value (output data a of the minimum value detection section 14-1 and the parity check result of the check node). The updated LLR′ is written back to the LMEMs 12-1 to 12-n.

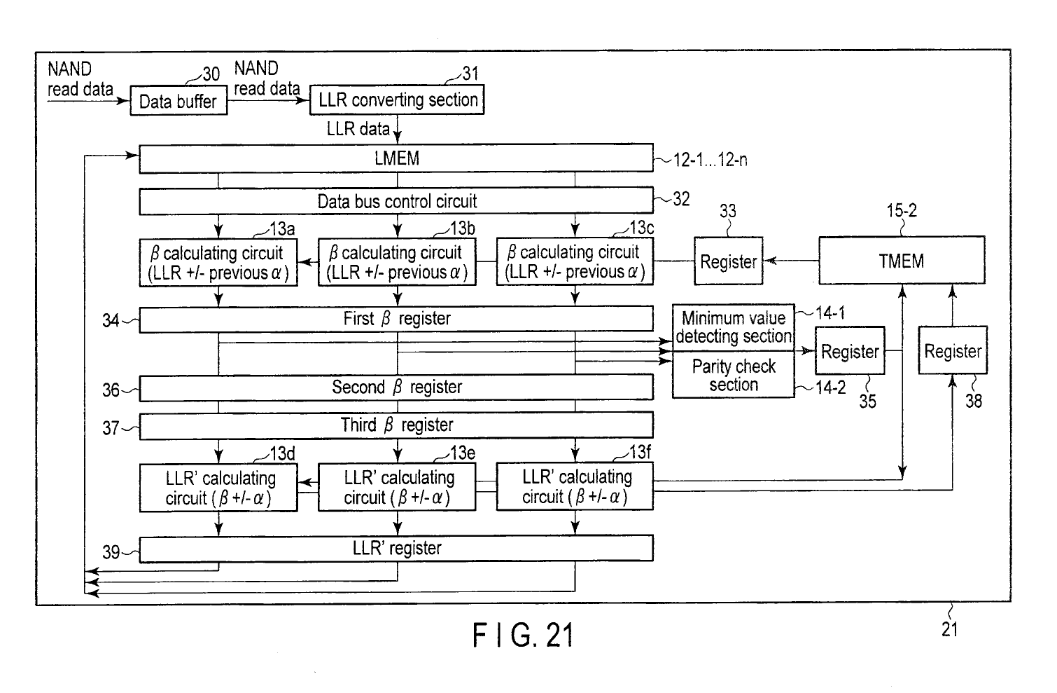

FIG. 21 is a block diagram illustrating an example of a concrete structure of the LDPC decoder according to the first mode. FIG. 21 shows a structure for executing a matrix parallel process by a pipeline configuration. In FIG. 21, the same components as those in FIG. 11 are denoted by like reference numerals.

Data read out from a NAND type flash memory, is delivered to a data buffer 30. This data is data to which parity data is added, for example, in units of the data, by an LDPC encoder (not shown). The data stored in the data buffer 30 is delivered to an LLR conversion section 31. The LLR conversion section 31 converts the data read out from the NAND type flash memory, to LLR data. The LLR data of the LLR conversion section 31, is supplied to the LMEMs 12-1 to 12-n.

The LMEMs 12-1 to 12-n are connected to first input terminals of β calculating circuits 13a, 13b and 13c via the data bus control circuit 32. The data bus control circuit 32 is a circuit which executes the dynamic allocation, and executes a control as to which of LLRs of variable nodes of column blocks is to be supplied to which of the calculating sections.

The β calculating circuits 13a, 13b and 13c constitute parts of the calculating sections 13-1 to 13-m. In the case of the example shown in FIG. 19, since the number of weights used in each row process is three, it should suffice if the number of calculating sections is three. Second input terminals of the β calculating sections 13a, 13b and 13c are connected to the intermediate value memory 15-2 via a register 33.

The intermediate value memory 15-2 stores the intermediate value data, for instance, α1 and α2 of the previous ITR, a sign of a of each variable node, INDEX, and a parity check result of each check node.

The β calculating circuits 13a, 13b and 13c execute calculating operations based on the LLR data supplied from the LMEMs 12-1 to 12-n and the intermediate value data supplied from the intermediate value memory 15-2.

Output terminals of the β calculating circuits 13a, 13b and 13c are connected to a first β register 34. The first β register 34 stores output data of the β calculating circuits 13a, 13b and 13c.

Output terminals of the first β register 34 are connected to the minimum value detection section 14-1 and parity check circuit 14-2. Output terminals of the minimum value detection section 14-1 and parity check section 14-2 are connected to the intermediate value memory 15-2 via a register 35.

FIG. 21 illustrates a case in which the minimum value detection section 14-1 and parity check section 14-2 are implemented in parallel to the first β register 34, but the configuration is not limited to this example. The minimum value detection section 14-1 and parity check section 14-2 may be configured in series to the first β register 34. In the case where the minimum value detection section 14-1 and parity check section 14-2 are implemented in parallel, a circuit configuration is implemented such that the processes of these components are executed in several clocks (e.g. 1 to 2 clocks).

The output terminals of the first β register 34 are connected to one-side input terminals of LLR′ calculating circuits 13d, 13e and 13f via a second β register 36 and a third β register 37. The second β register 36 stores output data of the first β register 34, and the third β register 37 stores output data of the second β register 36.

The second β register 36 and third β register 37 are disposed in accordance with the number of stages of a pipeline which is constituted by the minimum value detection section 14-1, parity check section 14-2 and register 35. FIG. 21 illustrates a circuit configuration in a case where the process of the minimum value detection section 14-1 and parity check section 14-2 is executed with one clock. When the number of clocks is 2, and additional β register is needed.

The LLR′ calculating circuits 13d, 13e and 13f constitute parts of the calculating sections 13-1 to 13-m, and are composed of three calculating circuits, like the β calculating circuits 13a, 13b and 13c. The other-side input terminals of the LLR′ calculating circuits 13d, 13e and 13f are connected to an output terminal of the register 35.

The LLR′ calculating circuits 13d, 13e and 13f execute a calculating operation based on the data β supplied from the third β register 37 and the intermediate value supplied from the register 35, and stores updated LLR's to an LLR′ register 39.

First output terminals of the LLR′ calculating circuits 13d, 13e and 13f are connected to input terminals of the LLR′ register 39, and second output terminals thereof are connected to the TMEM 15-2 via a register 38.

The LLR′ register 39 stores updated LLR's received from the LLR′ calculating circuits 13d, 13e and 13f. Output terminals of the LLR′ register 39 are connected to the LMEMs 12-1 to 12-n.

The register 38 stores INDEX data received from the LLR′ calculating circuits 13d, 13e and 13f. The register 38 is connected to the intermediate value memory 15-2.

The above-described LMEMs 12-1 to 12-n, the β calculating circuits 13a, 13b and 13c functioning as first calculating modules, the first β register 34, the register 35, the second β register 36, the third β register 37, the LLR′ calculating circuits 13d, 13e and 13f functioning as second calculating modules, and the LLR′ register 39 are included in each stage of the pipeline, and these circuits are operated by a clock signal (not shown).

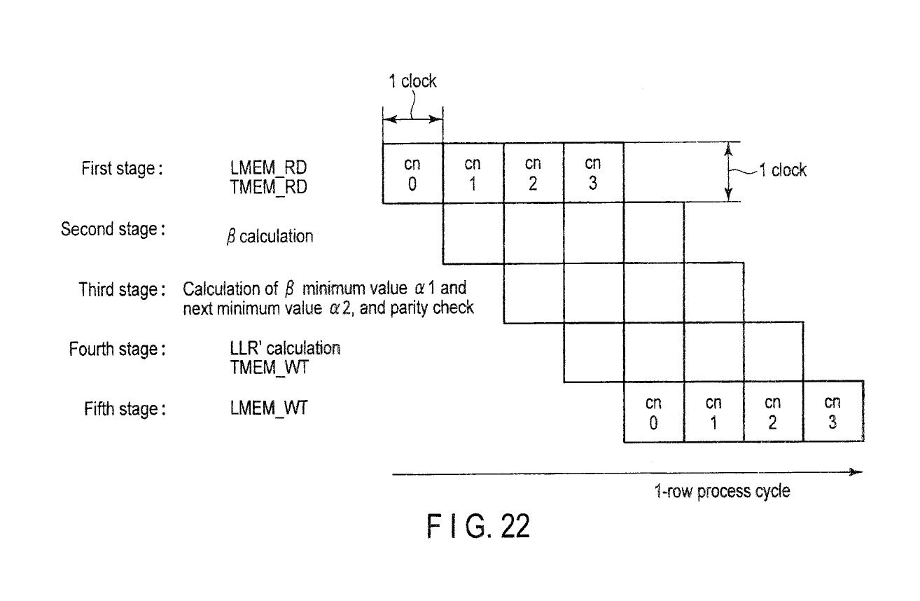

FIG. 22 is a view illustrating an example of an operation of the LDPC decoder according to the first mode, and illustrates an example of execution of a 1-clock cycle.

The LDPC decoder 21 executes, in a 1-row process, a process of check nodes, the number of which corresponds to the block size number. To begin with, LLRs of variable nodes are read out from the LMEMs 12-1 to 12-n, matrix processing is executed on the LLRs, and contents of the LLRs are updated. The updated LLRs are written back to the LMEMs 12-1 to 12-n. This series of processes is successively executed on the plural check nodes by the pipeline. In this mode, 1-row blocks are processed by five pipeline states.

Next, referring to FIG. 22, the process content in each stage is described.

FIG. 22 illustrates that the LDPC decoder 21 is composed of first to fifth stages, and in each stage the row process of each of check nodes cn0 to cn3 is executed by one clock.

### (First Stage)

To start with, the LLRs are read out from the LMEMs 12-1 to 12-n. Specifically, the LLRs of variable nodes, which are connected to a selected check node, are read out from the LMEMs 12-1 to 12-n. In the case of the first mode, three partial LLR data are read out from the LMEMs 12-1 to 12-n.

Further, intermediate value data is read out from the TMEM 15-2. The intermediate value data includes α1 and α2 of the previous ITR, the sign of α of each variable node, INDEX, and a parity check result of each check node. The intermediate value data is stored in the register 33. In this case, α is probability information from a check node to a bit node and is indicative of an absolute value of β in the previous ITR, α1 is a minimum value of the absolute value of β, and α2 is a next minimum value (α1<α2). INDEX is an identifier of a variable node having a minimum absolute value of β.

### (Second Stage)

The β calculating circuits 13a, 13b and 13c, which function as first calculating modules, execute calculating operations based on the LLRs from the LMEMs 12-1 to 12-n and the intermediate value data read out from the TMEM 15-2, thereby calculating β (logarithmic likelihood ratio). Specifically, each of the β arithmetic circuits 13a, 13b and 13c executes a calculating operation of β=(LLR)−(intermediate value data). In this calculating operation, with respect to a certain variable node, if the absolute value of β is minimum in the previous ITR, the next minimum value α2 is subtracted from β, and if the absolute value of β is not minimum, the minimum value α1 is subtracted from β. The sign of the intermediate value data is determined by the sign of α for each variable node.

The results of the calculating operations of the β calculating circuits 13a, 13b and 13c are stored in the first β register 34.

### (Third Stage)

The minimum value detection section 14-1 calculates, from the calculating result β stored in the first β register 34, the minimum value α1 of the absolute value of β, the next minimum value α2, and the identifier INDEX of a variable node having the minimum absolute value of β. In addition, the parity check section 14-2 executes a parity check of all check nodes.

The detection result of the minimum value detection section 14-1 and the check result of the parity check section 14-2 are stored in the register 35.

In addition, the minimum value detection section 14-1 and parity check section 14-2 execute a process based on the data of the first β register 34. When an executing result is stored in the register 35, the executing result is successively transferred to the second β register 36 and the third β register 37.

### (Fourth Stage)

The LLR′ calculating circuits 13d, 13e and 13f functioning as the second calculating modules execute calculating operations based on the check result of the parity check section 14-2, the calculating result 0 stored in the third β register 37, and the detection result detected by the minimum value detection section 14-1, and generate updated LLR′ data. Specifically, the LLR′ calculating circuits 13d, 13e and 13f execute LLR′ β+intermediate value data (α1 or α2 calculated in stage 3). Furthermore, the LLR′ calculating circuits 13d, 13e and 13f generate the sign of a of each variable node. The generation of the sign of a of each variable node is generated as follows.

If the LLR code is “0” and the result of the parity check of the check node is OK, β+α is calculated and the sign of a of each variable node becomes “0”.

If the LLR code is “0” and the result of the parity check of the check node is NG, β−α is calculated and the sign of a of each variable node becomes “1”.

If the LLR code is “1” and the result of the parity check of the check node is OK, β−α is calculated and the sign of a of each variable node becomes “1”.

If the LLR code is “1” and the result of the parity check of the check node is NG, β+α is calculated and the sign of α of each variable node becomes “0”.

The sign of α of each variable node is stored in the register 38.

Along with the above-described operation, the intermediate value data stored in the register 36 (α1, α2, the parity check result of each check node, the sign of α of each variable node, and INDEX data stored in the register 38) is stored in the intermediate-value memory 15-2.

### (Fifth Stage)

The LLR′ updated by the LLR′ calculating circuits 13d, 13e and 13f is stored in the LLR′ register 39, and the LLR′ stored in the LLR′ register 39 is written back in the LMEMs 12-1 to 12-n.

In the case of the architecture shown in FIG. 15 and FIG. 16, β calculated in the row process of loop 1 is written back to the LMEM 12, and the β is read out again from LMEM 12 in the column process of loop 2, and the updated LLR′ is calculated. If an intermediate buffer, which temporarily stores β, is disposed outside the LMEM 12, a capacity of the intermediate buffer becomes substantially equal to a capacity of the LMEM 12, and the circuit scale increases. Thus, β calculated in loop 1 is once written back to the LMEM. As a result, in the case of the architecture shown in FIG. 15 and FIG. 16, it is necessary to read the LMEM twice and write the LMEM twice, leading to an increase in access to the LMEM 12.

By contrast, according to the first mode, it should suffice if a capacity of each of the first β register 34, second β register 36 and third β register 37, which function as buffers for temporarily storing β, is such a capacity as to correspond to the number of variable nodes which are connected to the check node. Accordingly, the capacity of each of the first β register 34, second β register 36 and third β register 37 can be reduced.

Moreover, according to the first mode, since the first, second and third β registers 34, 36 and 37, which temporarily store β are provided, accesses to the LMEMs 12-1 to 12-n can be halved to one-time read and one-time write. Therefore, power consumption can greatly be reduced.

Besides, since the accesses to the LMEMs 12-1 to 12-n are halved, it is possible to avoid butting of accesses to the LMEMs 12-1 to 12-n in the pipeline process in the same row process. Thus, the apparent execution cycle number per 1 check node can be set at “1” (1 clock), and the process speed can be increased.

Furthermore, the minimum value detection section 14-1 and parity check section 14-2 are implemented in parallel in the third stage, and the minimum value detection section 14-1 and parity check section 14-2 are operated in parallel. Thus, for example, with 1 clock, the detection of the minimum value and the parity check can be executed.

### (Second Mode of Check-Node Based Parallel Process)

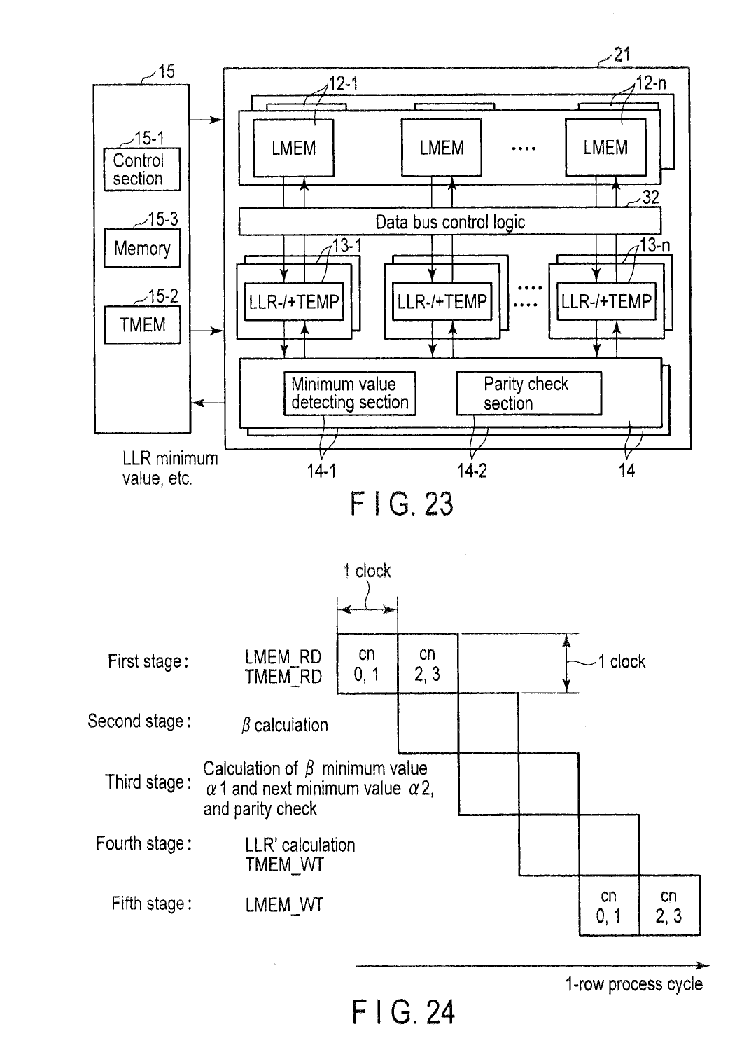

FIG. 23 is a block diagram illustrating an example of a schematic structure of an LDPC decoder according to a second mode of the check-node based parallel process.

FIG. 24 is a view illustrating an example of an operation of the LDPC decoder according to the second mode.

FIG. 23 and FIG. 24 illustrate the second mode, and the same parts as in the first mode are denoted by like reference numerals.

The LDPC decoder according to the second mode can flexibly select a degree of parallel process of circuits which are needed for calculating operations of the check nodes, in accordance with a required capability.

FIG. 23 and FIG. 24 illustrate an example in which the parallel process degree of check nodes is set at “2” (cp=2). In this case, two check nodes are selected at the same time, and the LLRs of the variable nodes, which are connected to each check node, are processed at the same time. Thus, the number of modules of the LMEMs 12-1 to 12-n is double the number of column blocks, and also there are provided double the number of modules of the calculating sections 13-1 to 13-m and the row-directional logics 14 including the minimum value detection section 14-1 and parity check section 14-2.

It is possible to double the number of input/output ports of the LMEMs 12-1 to 12-n, instead of doubling the number of modules of the LMEMs 12-1 to 12-n.

According to the above-described second mode, since the parallel process degree of check nodes is set at “2”, as illustrated in FIG. 24, it is possible to process two check nodes in 1 clock. Thus, the number of process cycles of one row can be halved, compared to the first mode shown in FIG. 22, and the process speed can be further increased.

The parallel process degree of check nodes is not limited to “2”, and may be set at “3” or more.

### (Third Mode of Check-Node Based Parallel Process)

In the above-described first and second modes, in order to make a description simple, a check matrix is set to be one row. However, an actual check matrix includes a plurality of rows, for example, 8 rows, and a column weight is 1 or more, for instance, 4.

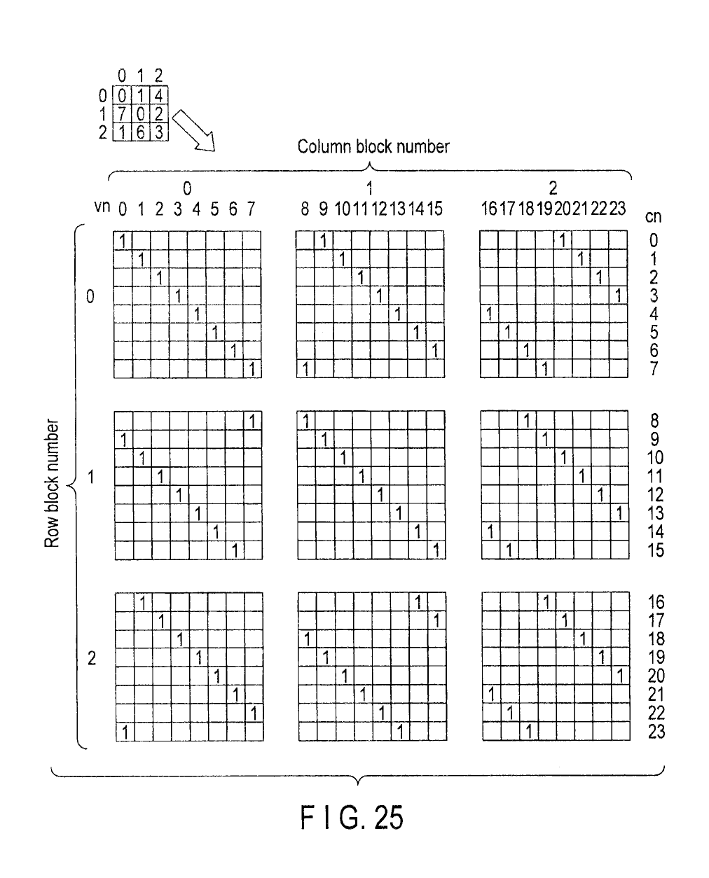

Referring to FIG. 25 to FIG. 29, a description is given of a control between row processes by the LDPC decoder 21 shown in FIG. 21.

FIG. 25 is a view illustrating an example of a check matrix according to a third mode of the check-node based parallel process. In this example of the check matrix, the block size is 8×8, the number of row blocks is 3, and the number of column blocks is 3.

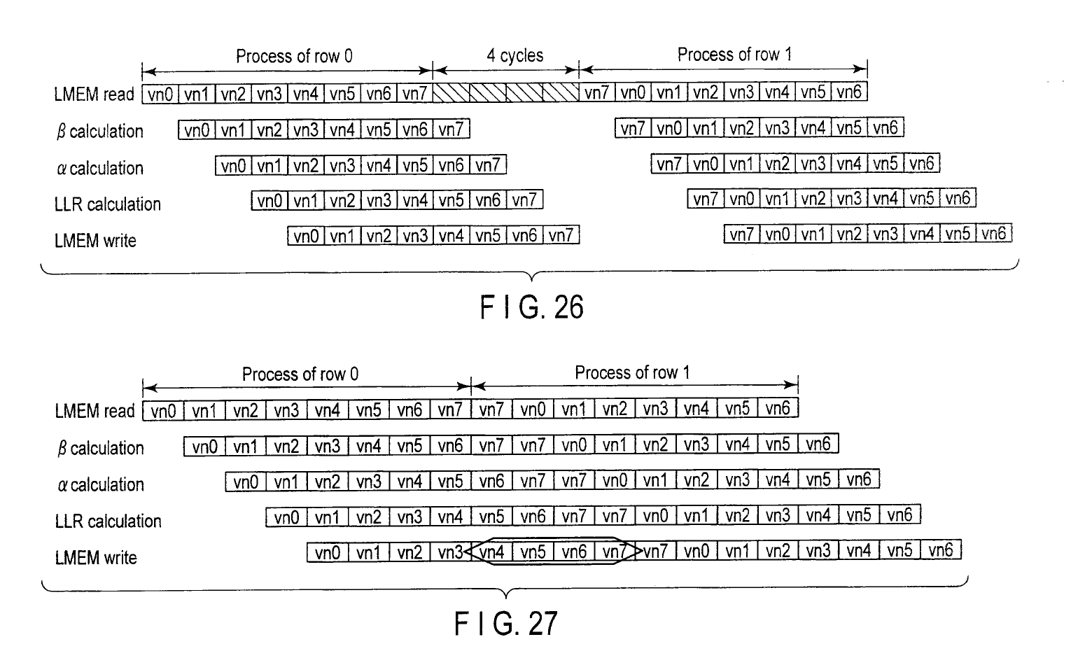

FIG. 26 is a view illustrating a first example of a control between the row processes using the check matrix according to the third mode.

FIG. 27 is a view illustrating a second example of a control between the row processes using the check matrix according to the third mode.

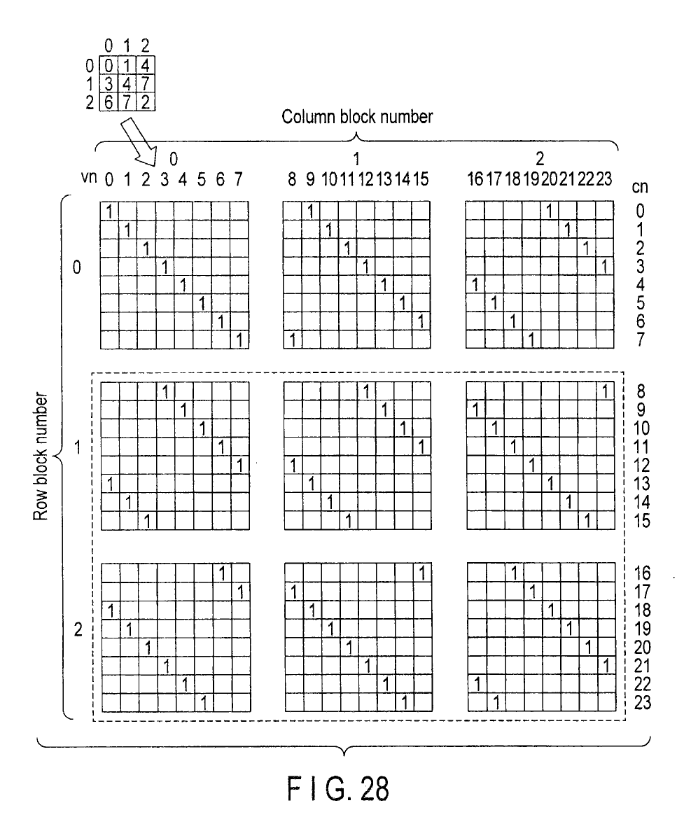

FIG. 28 is a view illustrating other example of a check matrix according to the third mode.

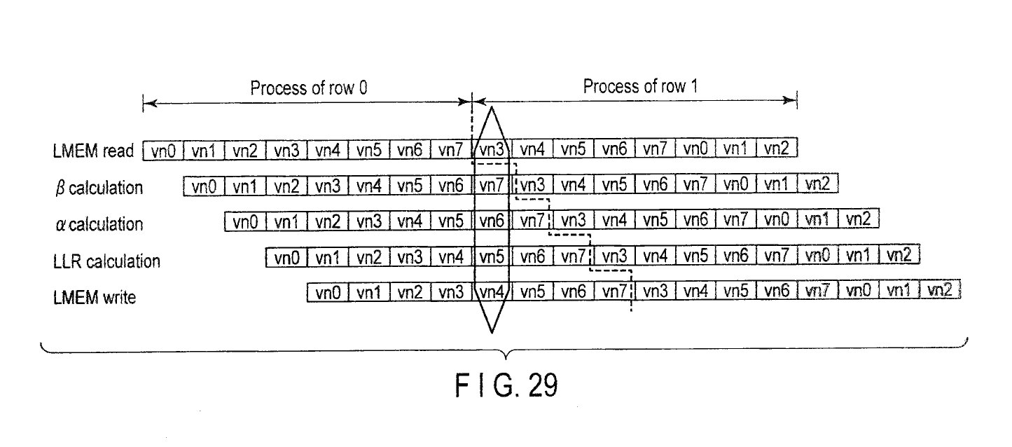

FIG. 29 is a view illustrating an example of a control between the row processes using other example of the check matrix according to the third mode.

FIG. 26, FIG. 27 and FIG. 28 illustrate a process of a column 0 block in a row 0 process and a row 1 process.

The LDPC decoder 21 updates the LLRs which is read out from the LMEMs 12-1 to 12-n, and writes the LLRs back to the LMEMs 12-1 to 12-n.

In the case where a process is executed by the LDPC decoder 21 by using the check matrix shown in FIG. 26, when a process of row 0 transitions to a process of row 1, LLR of the variable node vn7 is updated in the process of row 1. Before writing back, LLR node access of the variable node vn7 occurs. Thus, accesses of variable nodes are butting.

Specifically, in the check matrix shown in FIG. 25, if attention is paid to a column block 0, a row 0/column 0 block has a shift value “0”, and a row 1/column 0 block has a shift value “7”. In this state, as illustrated in FIG. 27, if a process of row 0 and a process of row 1 are successively executed, a read access to variable nodes vn0 to vn3 is possible since writing of updated LLR′ has been completed. However, read access can not be executed since updated LLR's of variable nodes vn4 to vn7 are not completed.

In this case, as illustrated in FIG. 26, a process of variable node vn7 of row 1 may be started from a cycle next to a cycle in which LLR′ of variable node vn7 of row 0 has been written in the LMEMs 12-1 to 12-n. In other words, an idle cycle may be inserted between row processes. In the case of this example, 4 idle cycles are inserted between the process of row 0 and the process of row 1.

In this manner, by inserting the idle cycle between row processes, the butting of variable node accesses can be avoided. On the other hand, as illustrated in FIG. 26, even without inserting the idle cycle between row processes, the butting of variable node accesses can be avoided by adjusting the block shift value when the check matrix is designed.

For example, the block shift values of the check matrix shown in FIG. 25 are adjusted as in a check matrix shown in FIG. 28. Thereby, the variable node access butting can be avoided without inserting the idle cycle between the row processes. In the case of the check matrix shown in FIG. 28, the shift values of matrix blocks in a part indicated by a broken line are made different from those in the check matrix shown in FIG. 25.

FIG. 29 illustrates row processes according to the check matrix shown in FIG. 28. In this manner, by varying the shift values of the check matrix, the variable node access butting can be avoided without inserting the idle cycle between the row processes, since the write of variable node vn3 of row 0 has been completed when variable node vn3 of row 1 is accessed.

According to the above-described third mode, by inserting the idle cycle between the row processes or by adjusting the shift value of the check matrix, the butting of variable node accesses in the LMEMs 12-1 to 12-n can be avoided.

(Fourth Mode of Check-Node Based Parallel Process)

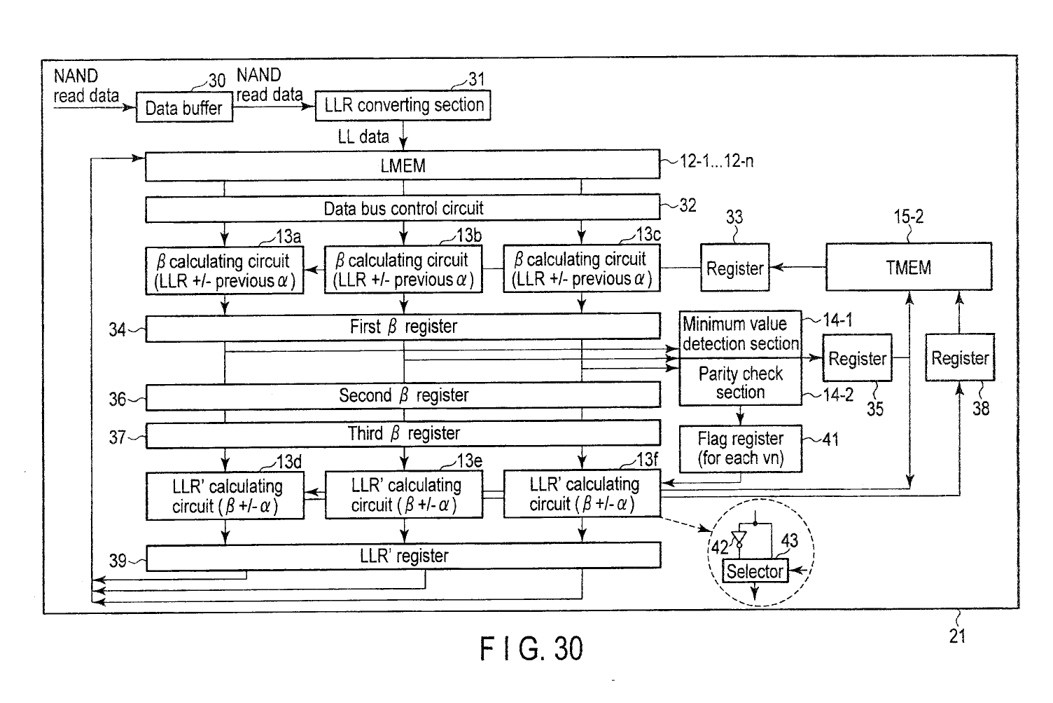

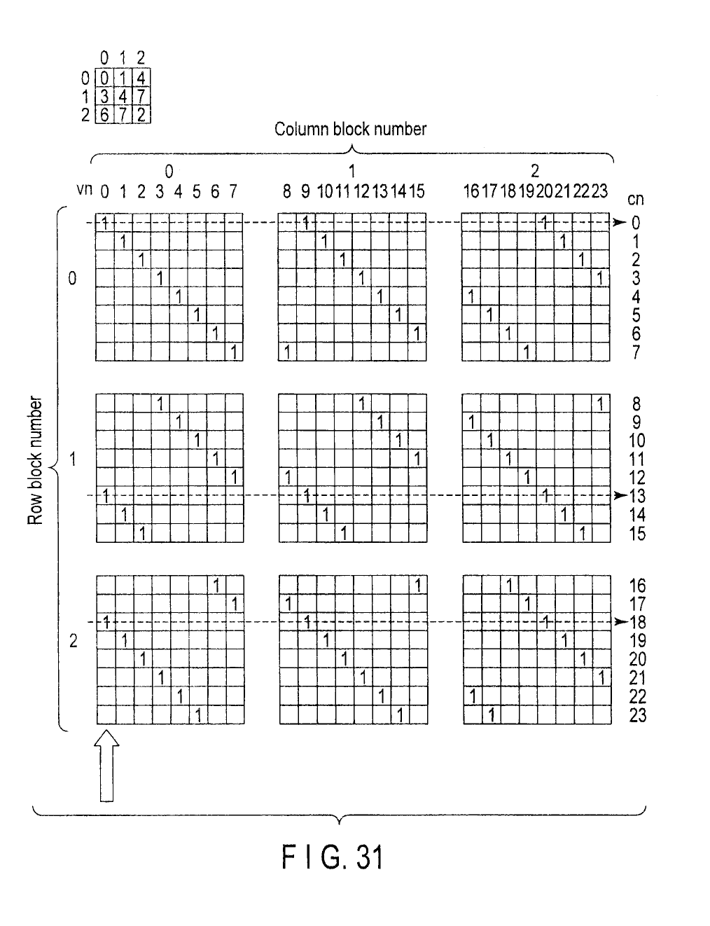

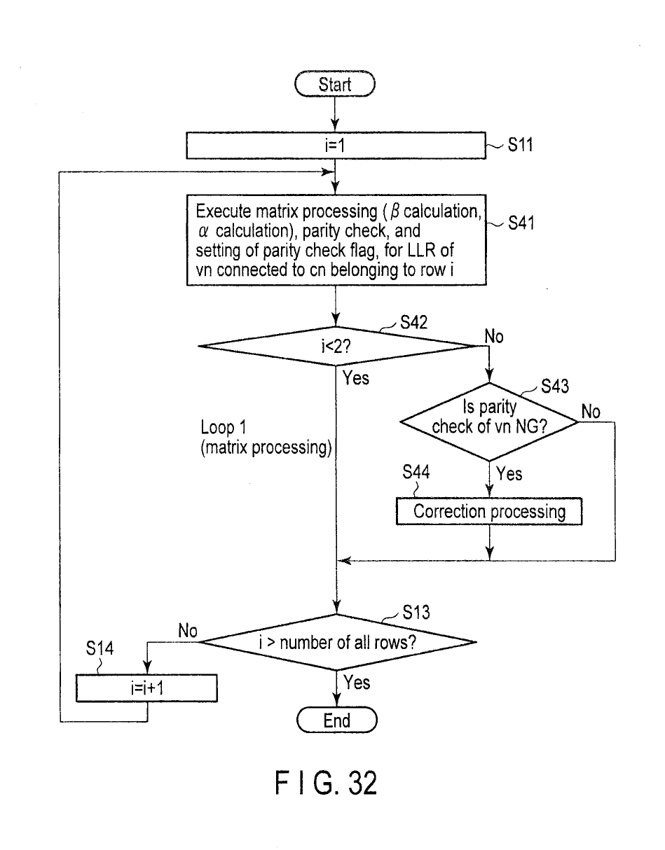

FIG. 30, FIG. 31 and FIG. 32 illustrate a fourth mode of the check-node based parallel process, and the same parts as in the first mode are denoted by like reference numerals.

FIG. 30 is a block diagram illustrating an example of a concrete structure of the LDPC decoder according to the fourth mode of the check-node based parallel process.

In the fourth mode, LDPC correction is made with plurality of decoding algorithms by using a result of parity check.

In the fourth mode, for example, when decoding is executed with a Mini-SUM algorithm, LLR is updated by making additional use of bit flipping (BF) algorithm. Correction is made with a plurality of algorithms by using an identical parity check result detected from an intermediate value of LLR. Thereby, a capability can be improved without lowering an encoding ratio and greatly increasing a circuit scale.

In the LDPC decoder 21 shown in FIG. 30, a flag register 41 is connected to the parity check section 14-2. The flag register 41 is connected to the LLR′ calculating circuits 13d, 13e and 13f.

When the parity check section 14-2 has executed parity check of check nodes, the flag register 41 stores a parity check result of the check nodes as a 1-bit flag (hereinafter also referred to as “parity check flag”) with respect to each variable node.

FIG. 31 is a view illustrating an example of a check matrix according to the fourth mode.

As shown in FIG. 31, in this embodiment, the check matrix has a block size 8×8, three row blocks, three column blocks, and a column weight “3”. Thus, one variable node is connected to three check nodes, and a three-time parity check result is stored in the flag register 41 as a 1-bit flag.

FIG. 32 is a flowchart illustrating an example of an operation of the LDPC decoder 21 according to a fourth mode.

As illustrated in FIG. 32, each time a 1-row block process is executed, a parity check of a check node is executed. At a start time of correction processing, an initial value “0” is set to the flag register 41. If the parity check fails to pass, OR data, which is obtained based on OR operation between a stored value of the flag register 41 and “1”, is stored in the flag register 41. The OR data, which is obtained based on OR operation between the stored value of the flag register 41 and “0”, is stored in the flag register 41. In the case where the flag of a certain variable node is “1” at a time when a three-row block process, that is, 1 ITR, has been finished, it is indicated that the certain variable node fails to pass three times parity checks (S41).

For example, in the check matrix shown in FIG. 31, paying attention to a variable node vn0, when all parity checks of check nodes cn0, 13, 18, which are connected to the variable node vn0, failed to pass, the parity check flag of the variable node vn0 is set at “1”.

In the second and subsequent ITR, the LLR′ calculating circuits 13d, 13e and 13f execute calculating processes in accordance with the parity check flag supplied from the flag register 41, with respect to each row block process (S42, S43).

Specifically, the LLR′ calculating circuits 13d, 13e and 13f execute, in addition to a normal LLR update process, unique LLR correction processing for, for example, a variable node with a parity check flag “1” (S44).

As the unique correction processing, for example, a process according to the BF algorithm is applied. Specifically, when all parity check results of three check nodes, which are connected to the variable node vn0, fail to pass, it is highly probable that the variable node vn0 is erroneous. Thus, correction is made in a manner to lower the absolute value of the LLR of the variable node vn0. To be more specific, the LLR′ calculating circuit 13d, 13e, 13f increases, by several times, the value of α which is supplied from the register 35, and updates the LLR by using this a. In this manner, the LLR of the variable node, which is highly probably erroneous, is further lowered.

The LLR′ calculating circuit 13d, 13e, 13f does not execute the unique correction processing for the variable node with a parity check flag “0”.

The above-described unique correction processing means that a single parity check is used in the LDPC decoder 21, and a decoding process is executed by using both the mini-sum algorithm and applied BF algorithm.

In the BF decoding that is one of decoding algorithms of LDPC, LLR is not used and only the parity check result of the check node is used. Thus, the BF decoding has a feature that it has a high tolerance to a hard error (HE) on data with an extremely shifted threshold voltage, which has been read out of a NAND type flash memory. Therefore, the BF decoding process can be added to the LDPC decoder 21 which determines the check node for which a parallel process is executed by the variable node base, as described above.

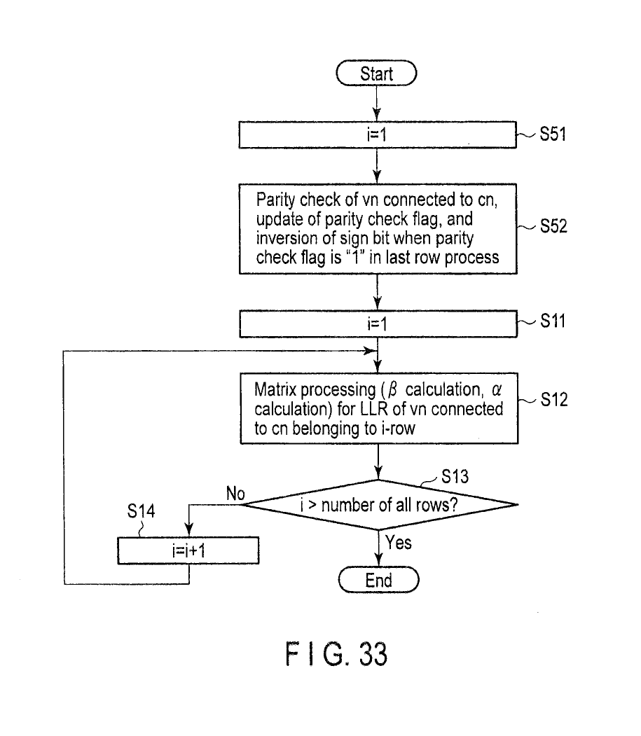

FIG. 33 is a flowchart illustrating a modified example of an operation of the LDPC decoder 21 according to the fourth mode.

As shown in FIG. 33, before the normal mini-sum decoding process illustrated in steps S11 to S14, the parity check of all check nodes and the update of the parity check flag are executed. In the final row process, if the parity check flag is “1”, the sign bit is BF decoded (bit inversion). According to this modification, a hard error tolerance of the LDPC decoder 21 can be enhanced.

The BF decoding can be executed by using the calculating circuits for mini-sum as such. In the normal mini-sum calculating circuit, only the most significant bit (sign bit) of the LLR is received, and the calculation of β and the detection of the minimum value of β is not executed. It should suffice if the parity check of all check nodes and the update of the parity check flag are executed.

For example, as shown in FIG. 30, a sign inversion process is configured by an inverter circuit 42 and selector 43 provided in the LLR′ calculating circuits 13d, 13e, 13f. Specifically, a sign bit, which is inverted by the inverter circuit 42, is supplied to a first input terminal of the selector 43, and a sign bit is supplied to a second input terminal of the selector 43. The selector 43 selects one of the inverted sign bit supplied to the first input terminal and the sign bit supplied to the second input terminal in accordance with the parity check flag supplied from the flag register 41. With this structure, the fourth mode can easily be implemented.

With the above-described fourth mode, too, the same advantageous effects as with the first mode can be obtained. Moreover, according to the fourth mode, check nodes, which are connected to the same variable node, are processed batchwise, and sequential processes in the row direction are also executed, and furthermore the LLR is updated with an addition of the BF algorithm. In this manner, by correcting an error with use of plural algorithms, the capability can be improved without lowering an encoding ratio and greatly increasing the circuit scale.

In the BF decoding, LLR is not used, and only the parity check result of the check node is used. Thus, since the tolerance to data with an extremely shifted threshold voltage, which has been read out from the NAND type flash memory, is high, it is possible to realize ECC of a multilevel (MLC) NAND type flash memory which stores plural bits in one memory cell.

The LDPC decoders described in the first to fourth modes process data of NAND type flash memories. However, the embodiments are not limited to these examples, and are applicable to a data process in a communication device, etc.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An error correction decoder comprising:
a converting section which converts error correction code (ECC) data into logarithm likelihood ratio data and stores the logarithm likelihood ratio data in a first memory section;
a selecting section which selects, based on a check matrix comprising matrix blocks arranged along rows and columns, data used for matrix processing applied to a process target row among the rows from the logarithm likelihood ratio data stored in the first memory section, and stores the data in a second memory section;
a calculating section which executes the matrix processing based on the data stored in the second memory section, and writes updated data back to the second memory section;
a parity check section which performs a parity check based on a calculating result of the calculating section; and
an updating section which updates the logarithm likelihood ratio data stored in the first memory section based on the updated data stored in the second memory section.

2. The error correction decoder of claim 1, wherein
the ECC data is low density parity check (LDPC) data;
the selecting section selects the data corresponding to all variable nodes having connective relation to a process target check node;
the error correction decoder further comprises a minimum value detecting section which detects a minimum value α of absolute values of values βs obtained by the matrix processing; and
the calculating section calculates the value β, based on the data and the minimum value α for a previous process unit, for the all variable nodes having connective relation to the process target check node, and produces the updated data based on the value β and the minimum value α.

3. The error correction decoder of claim 2, wherein the calculating section calculates the value β by subtracting the minimum value α for the previous process unit from the data, adds the value β to the minimum value α, and produces the updated data.

4. The error correction decoder of claim 2, wherein the selecting section, the calculating section, and the updating section execute a parallel process of the variable nodes based on the process target check node.

5. The error correction decoder of claim 1, wherein the selecting section, the calculating section, and the updating section execute a pipeline process.

6. The error correction decoder of claim 5, wherein, in a case where reading out and updating with respect to an address of the first memory section collide with each other, data corresponding to the address is once read out from the second memory section instead of the reading out from the first memory section, and is stored in the second memory section.

7. The error correction decoder of claim 5, wherein matrix blocks being non-zero matrices are prevented from being successively arranged along a column direction in at least one part of the check matrix.

8. The error correction decoder of claim 5, wherein
the second memory section includes a plurality of memory sections, and
the selecting section switches a memory destination between the plurality of memory sections

9. The error correction decoder of claim 7, wherein at least two matrix blocks being zero matrices are arranged between the matrix blocks being non-zero matrices along the column direction in the at least one part of the check matrix.

10. The error correction decoder of claim 7, wherein an idle state is inserted between a process for a first row of the check matrix and a process for a second row of the check matrix in a case where the matrix blocks being non-zero matrices are successively arranged along the column direction between the first row and the second row.

11. The error correction decoder of claim 1, wherein the calculating section executes correction processing for the data when a check result of the parity check section includes an error.

12. The error correction decoder of claim 1, wherein the second memory section is a register performing much quicker access than the first memory section.

13. A nonvolatile semiconductor memory device comprising:
a nonvolatile semiconductor memory;
a converting section which converts error correction code (ECC) data read out from the nonvolatile semiconductor memory into logarithm likelihood ratio data and stores the logarithm likelihood ratio data in a first memory section;
a selecting section which selects, based on a check matrix comprising matrix blocks arranged along rows and columns, data used for matrix processing applied to a process target row among the rows from the logarithm likelihood ratio data stored in the first memory section, and stores the data in a second memory section;
a calculating section which executes the matrix processing based on the data stored in the second memory section, and writes updated data back to the second memory section;
a parity check section which performs a parity check based on a calculating result of the calculating section; and
an updating section which updates the logarithm likelihood ratio data stored in the first memory section based on the updated data stored in the second memory section.

14. An error correction method comprising:
converting error correction code (ECC) data into logarithm likelihood ratio data and storing the logarithm likelihood ratio data in a first memory section;
selecting, based on a check matrix comprising matrix blocks arranged along rows and columns, data used for matrix processing applied to a process target row among the rows from the logarithm likelihood ratio data stored in the first memory section, and storing the data in a second memory section;
executing the matrix processing based on the data stored in the second memory section, and writing updated data back to the second memory section;
checking a parity based on a result of the matrix processing; and
updating the logarithm likelihood ratio data stored in the first memory section based on the updated data stored in the second memory section.

15. The error correction method of claim 14, further comprising executing correction processing for the data by the matrix processing when a result of the checking includes an error.
